(19) United States
(12) Patent Application Publication
(10) Pub. No.: US 2021/0286009 A1
(43) Pub. Date: Sep. 16, 2021

(54) POWER STORAGE DEVICE, INFORMATION PROCESSING DEVICE, REPORTING METHOD, ESTIMATION METHOD, RECORDING MEDIUM, AND POWER STORAGE SYSTEM

(71) Applicant: NEC Corporation, Tokyo (JP)

(72) Inventor: Hiroshi KAJITANI, Tokyo (JP)

(73) Assignee: NEC Corporation, Tokyo (JP)

(21) Appl. No.: 16/328,355

(22) PCT Filed: Aug. 25, 2017
(86) PCT No.: PCT/JP2017/030460

§ 371 Date: Feb. 26, 2019

(30) Foreign Application Priority Data
Aug. 31, 2016 (JP) 2016-169444

(51) Int. Cl. G01R 31/382; H01M 10/44; H01M 10/48; H02J 3/28; G01R 31/396; H02J 7/00

(52) U.S. Cl. CPC G01R 31/382; H01M 10/44; H02J 7/0048; H02J 3/28; G01R 31/396; H01M 10/48

(57) ABSTRACT

In order to provide a technology with which a load associated with a process for determining a state of a storage battery can be reduced, a power storage device includes: a measurement unit 125 that measures a state of a storage battery 115; a memory unit 135 that stores a piece of state data indicating the state measured by the measurement unit 125 in association with a measurement time at which the state is measured; a transmission unit 145 that transmits to a communication network a piece of state data stored in the memory unit 135; and a control unit 155 that controls the transmission unit 145 in such a way that each piece of state data transmitted by the transmission unit 145 is a piece of the state data the measurement time of which differs each day.

### TECHNICAL FIELD

The present invention relates to a power storage device, an information processing device, a reporting method, an estimation method, a program, a recording medium, and a power storage system.

### BACKGROUND ART

Recent years, use of storage batteries (secondary batteries) has been popularized in various scenes. A storage battery deteriorates due to repeated charging and discharging and duration of use. A technology in which, in order to monitor a state of a storage battery, information indicating a state of the storage battery is transmitted to a maintenance server at a predetermined transmission timing has been developed (see, for example, PTL 1).

Technologies related to storage batteries include the following technologies. For example, PTL 2 describes a technology for estimating remnant life of storage battery cells constituting an assembled battery. PTL 3 describes a technology for equalizing deterioration of storage batteries mounted on vehicles. PTL 4 describes a technology for charging and discharging a storage battery within a range of chargeable/dischargeable capacity of the storage battery in response to a request from an energy management system. Although not a technology directly related to storage batteries, PTL 5 describes a technology for suppressing the amount of consumption of a battery by adjusting a cycle at which positional information of a terminal is transmitted.

### CITATION LIST

### Patent Literature

[PTL 1] WO 2015/129321 A
[PTL 2] JP 2006-300561 A
[PTL 3] JP 2015-27223 A
[PTL 4] WO 2015/040724 A
[PTL 5] JP 2010-212906 A

### SUMMARY OF INVENTION

### Technical Problem

In order to have an accurate understanding of states of a storage battery, a lot of information on the storage battery is required to be collected. For this reason, when the technology described in PTL 1 is used, information is required to be transmitted at a lot of transmission timings. There is a problem in that this requirement causes a load on the side receiving the information, such as a maintenance server (monitoring server), to be increased. The other patent literatures described above are not technologies that are capable of solving the problem described above.

An object of the present invention is to provide a power storage device, an information processing device, a reporting method, an estimation method, a program, and a power storage system that solve the problem described above.

### Solution to Problem

A power storage device according to the present invention includes:

a measurement unit that measures a state of a storage battery;

a memory unit that stores a piece of state data that indicates a state measured by the measurement unit in association with a measurement time at which the state is measured;

a transmission unit that transmits a piece of state data stored in the memory unit to a communication network; and

a control unit that controls the transmission unit in such a way that each piece of state data transmitted by the transmission unit is a piece of state data the measurement time of which differs each day.

An information processing device according to the present invention includes:

a reception unit that receives a plurality of pieces of state data that are transmitted from a power storage device and that indicate states of a storage battery that the power storage device includes; and

an estimation unit that estimates a deterioration state of the storage battery, based on the states that the plurality of pieces of state data received by the reception unit indicate.

A reporting method according to the present invention includes the steps of:

measuring a state of a storage battery;

storing a piece of state data that indicates the measured state in association with a measurement time at which the state is measured in a database; and

transmitting, among pieces of state data stored in the database, a piece of state data the measurement time of which differs each day to a communication network.

An estimation method according to the present invention includes the steps of:

receiving a plurality of pieces of state data that are transmitted from a power storage device and that indicate states of a storage battery that the power storage device includes; and

estimating a deterioration state of the storage battery, based on states that the received plurality of pieces of state data indicate.

A program according to the present invention is a program for causing a computer to perform the steps of:

measuring a state of a storage battery;

storing a piece of state data that indicates the measured state in association with a measurement time at which the state is measured in a database; and

transmitting, among pieces of state data stored in the database, a piece of state data the measurement time of which differs each day to a communication network.

Another program according to the present invention is a program for causing a computer to perform the steps of:

receiving a plurality of pieces of state data that are transmitted from a power storage device and that indicate states of a storage battery that the power storage device includes; and

estimating a deterioration state of the storage battery, based on states that the received plurality of pieces of state data indicate.

The object of the present invention can also be achieved by a recording medium recording the programs described above.

A power storage system according to the present invention is

a power storage system including an information processing device and a plurality of power storage devices, in which

each of the plurality of power storage devices includes:
a measurement unit that measures a state of a storage battery that the power storage device includes;
a transmission unit that transmits a piece of state data that indicates a state measured by the measurement unit to the information processing device; and
a control unit that controls a transmission timing at which the transmission unit transmits the piece of state data, in which
the control unit controls the transmission timing in such a way that the transmission unit transmits the piece of state data at a timing that is mutually different from timings at which a power storage devices(s) other than the power storage device among the plurality of power storage devices transmit(s) a piece(s) of state data.

### Advantageous Effects of Invention

As described above, in the present invention, it is possible to reduce a load on processing for determining states of a storage battery.

### BRIEF DESCRIPTION OF DRAWINGS

FIG. 1 is a diagram illustrating an example of changes in a capacity deterioration amount of a storage battery depending on differences in usage modes and usage environments of the storage battery;

FIG. 2 is a diagram illustrating an example of an equivalent circuit of a storage battery;

FIG. 3 is a diagram illustrating an example of a time response in voltage at the time of charging or charge end of a storage battery;

FIG. 4 is a diagram illustrating a first example embodiment using power storage devices of the present invention;

FIG. 5 illustrates an example of an internal configuration of each of the power storage devices illustrated in FIG. 4;

FIG. 6 is a diagram illustrating an example of associations between pieces of state data and measurement times that a memory unit illustrated in FIG. 5 stores;

FIG. 7 is a diagram for a description of an example of pieces of state data that a transmission unit illustrated in FIG. 5 transmits and the transmission of which is controlled by a control unit illustrated in FIG. 5;

FIG. 8 is a flowchart for a description of an example of a reporting method in each of the power storage devices illustrated in FIG. 5;

FIG. 9 illustrates an example of an internal configuration of an information processing device illustrated in FIG. 4;

FIG. 10 is a flowchart for a description of an example of an estimation method in the information processing device illustrated in FIG. 9;

FIG. 11 is a diagram illustrating an example of a result of superimposition of pieces of state data on one another by an estimation unit illustrated in FIG. 9;

FIG. 12 is a diagram illustrating a second example embodiment (a power storage system) using power storage devices of the present invention;

FIG. 13 is a diagram illustrating an example of an internal configuration of each of the power storage device illustrated in FIG. 12;

FIG. 14 is a diagram illustrating an example of transmission timings of pieces of state data from the power storage devices that are controlled by control units illustrated in FIG. 13;

FIG. 15 illustrates an example of an internal configuration of an information processing device illustrated in FIG. 12;

FIG. 16 is a sequence diagram for a description of an example of an estimation method in the power storage system illustrated in FIG. 12;

FIG. 17 is a diagram illustrating a third example embodiment using power storage devices of the present invention;

FIG. 18 illustrates an example of an internal configuration of an information processing device illustrated in FIG. 17;

FIG. 19 is a diagram illustrating an example of a result of superimposition of sets of pieces of state data (measurement data) transmitted from power storage devices on one another by an estimation unit illustrated in FIG. 18;

FIG. 20 is a flowchart for a description of an estimation method in the information processing device illustrated in FIG. 18;

FIG. 21 is a diagram illustrating a fourth example embodiment using power storage devices of the present invention;

FIG. 22 illustrates an example of an internal configuration of each of the power storage devices illustrated in FIG. 21;

FIG. 23 is a diagram for a description of an example of transmission timings of pieces of state data that a transmission unit illustrated in FIG. 22 transmits and the transmission of which is controlled by a control unit illustrated in FIG. 22;

FIG. 24 is a flowchart for a description of an example of a reporting method in each of the power storage devices illustrated in FIG. 22;

FIG. 25 is a diagram illustrating a fifth example embodiment using power storage devices of the present invention;

FIG. 26 illustrates an example of an internal configuration of each of the power storage devices illustrated in FIG. 25;

FIG. 27 is a diagram for a description of an example of pieces of state data that a transmission unit illustrated in FIG. 26 transmits and the transmission of which is controlled by a control unit illustrated in FIG. 26;

FIG. 28 is a flowchart for a description of an example of a reporting method in each of the power storage devices illustrated in FIG. 26;

FIG. 29 is a diagram illustrating a sixth example embodiment using a power storage device of the present invention;

FIG. 30 is a flowchart for a description of an example of a reporting method in the power storage device illustrated in FIG. 29;

FIG. 31 is a diagram illustrating a seventh example embodiment (a power storage system) using power storage devices of the present invention;

FIG. 32 is a diagram illustrating an example of an internal configuration of each of the power storage devices illustrated in FIG. 31;

FIG. 33 is a sequence diagram for a description of an example of an estimation method in the power storage system illustrated in FIG. 31;

FIG. 34 is a diagram illustrating an example embodiment of an information processing device of the present invention; and

FIG. 35 is a flowchart for a description of an estimation method in the information processing device illustrated in FIG. 34.

### EXAMPLE EMBODIMENT

Example embodiments of the present invention will be described below with reference to the drawings.

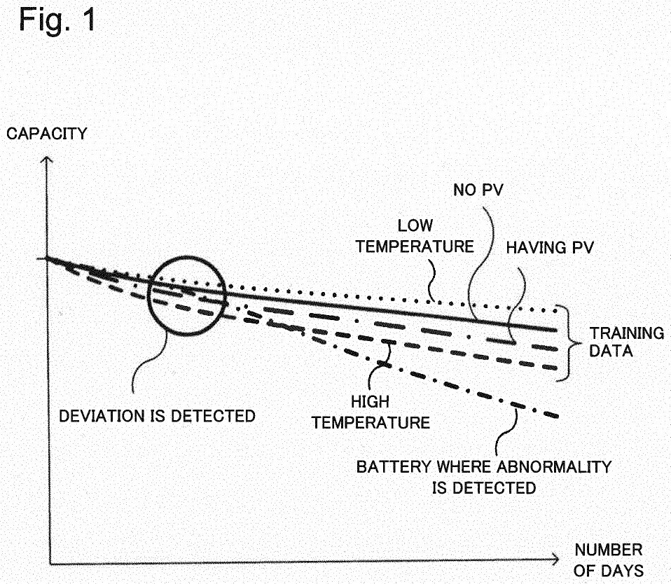

FIG. 1 is a diagram illustrating an example of changes in a capacity deterioration amount of a storage battery depending on differences in usage modes and usage environments of the storage battery. As illustrated in FIG. 1, progress of deterioration of a storage battery used in a high temperature environment, in general, tends to be faster than progress of deterioration of a storage battery used in a low temperature environment. Cooperative operation is sometimes performed between a storage battery and a photovoltaic (PV). Such a storage battery is charged during a period of time (for example, night-time) when the power price is low. Power consumption during daytime is met by power generated by a PV. When power generated by the PV exceeds power consumption, the surplus power is sold. Since, on this occasion, power charged in the storage battery cannot be sold, the power charged in the storage battery is scarcely used during daytime and the storage battery is kept in a fully-charged state. The storage battery starts discharging after sunset, when the amount of generated power by the PV is small.

The amount of generated power by photovoltaic power generation greatly differs area by area. In Japan, sunshine duration in winter time on the Japan Sea side widely differs from that on flatland on the Pacific Ocean side, where sunshine duration is comparatively long. Further, during a single day, the amount of generated power widely fluctuates depending on whether the weather is sunny, cloudy, or rainy. For this reason, when the weather changes from rainy to sunny, there is a possibility that, after power in a storage battery has been used up, the storage battery is charged by a PV. Since, in this case, the storage battery is charged and discharged twice a day, deterioration in capacities of storage batteries substantially vary with respect to each storage battery even when periods from installation of the respective storage batteries are the same. Therefore, a storage battery that performs cooperative operation with a PV, when stored fully-charged, is likely to deteriorate faster than a storage battery that does not perform cooperative operation with a PV.

Regardless of whether or not cooperative operation with a PV is performed, deterioration speed of a storage battery in which an abnormality has been detected is likely to be faster than deterioration speed of a storage battery in which no abnormality has been detected. As illustrated in FIG. 1, when, with respect to a storage battery, a deviation from a normal deterioration inclination is detected, it is possible to determine that an abnormality has occurred in the storage battery. A way to use a storage battery in such a way as to constantly stockpile 20% to 30% of the storage battery capacity as an emergency power source tends to cause deterioration of the storage battery to progress faster than a way to use the storage battery in such a way as to use up the storage battery capacity every time.

Extraction, on a cloud, of a correlation comparing states of storage batteries in which deterioration as described above has been progressing with each other enables a tendency of deterioration in the capacity of a storage battery that is used under a similar condition to be identified. Thus, even when detailed measurement data of a storage battery are not available, it becomes possible to estimate future lifespan of the storage battery that has a different period of use. When a tendency of a slight deviation in the tendency of deterioration in capacity of a storage battery from those of storage batteries used under the same condition occurs, there is a high possibility that deterioration different from regular deterioration has occurred in the storage battery. Thus, estimating a malfunction in a storage battery in advance by keeping close watch on the storage battery from the cloud and preparing for replacement of a component and the like enables inconvenience for users to be eliminated.

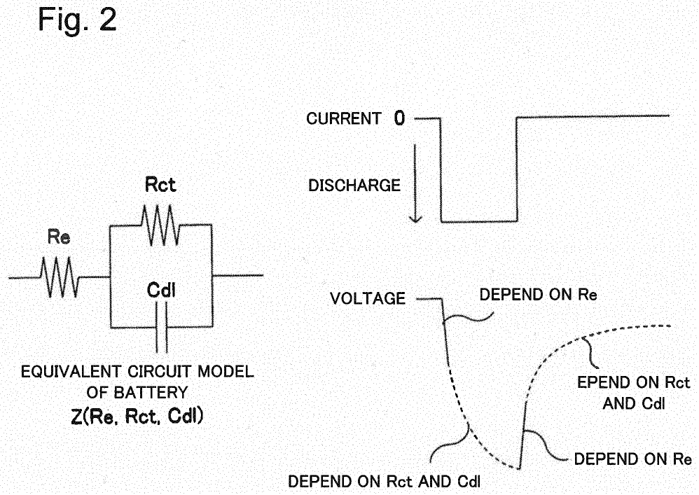

FIG. 2 is a diagram illustrating an example of an equivalent circuit of a storage battery. As illustrated in FIG. 2, a storage battery can be approximated by an equivalent circuit constituted by two resistors and a capacitor. When discharging starts, voltage of the storage battery depends on a resistor Re because current includes high frequency components, and, subsequently, when the high frequency components of the current have subsided, the voltage depends on a resistor Rct and a capacitor Cdl. When discharging ends, the voltage depends on a resistor Re because the current includes high frequency components, and, subsequently, the voltage depends on a resistor Rct and a capacitor Cdl.

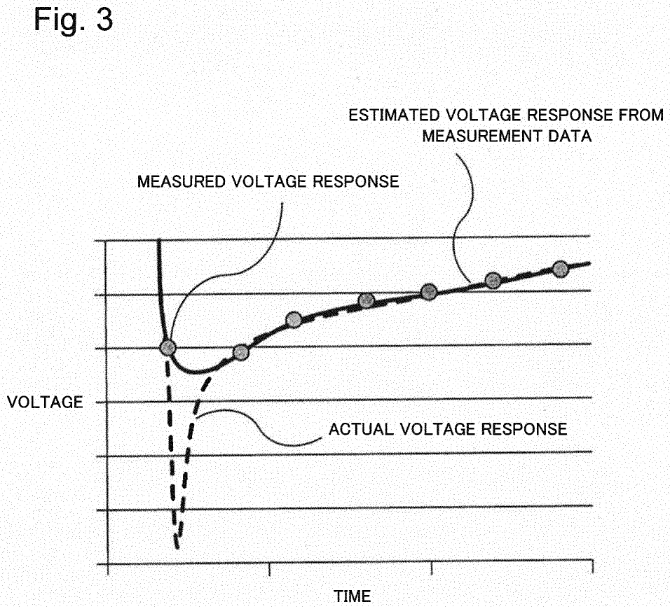

FIG. 3 is a diagram illustrating an example of a time response in voltage at the time of charging or charge end of a storage battery. In general, internal resistance exists in a storage battery, and, while current flows through the storage battery, a voltage rise (at the time of charging) or a voltage fall (at the time of discharging) equivalent to a voltage expressed by JR (where I and R denote current and internal resistance, respectively) is superimposed on an actual voltage across the storage battery. Since, at a moment when charging or discharging ends, the IR component disappears, measurement of a voltage component in this period enables the internal resistance of the storage battery to be measured. Internal resistance of a storage battery tends to increase as the number of charging/discharging cycles increases and serves as an index for estimating capacity deterioration and output deterioration of the storage battery. When these values are estimated using data collected on a cloud, a large measurement interval of voltage values causes values changing instantaneously to be overlooked. On the other hand, with regard to relaxation characteristics that changes in a long time-scale in contrast to an instantaneous response, it is possible to achieve a sufficient estimation accuracy even with a comparatively long data collection interval.

### First Example Embodiment

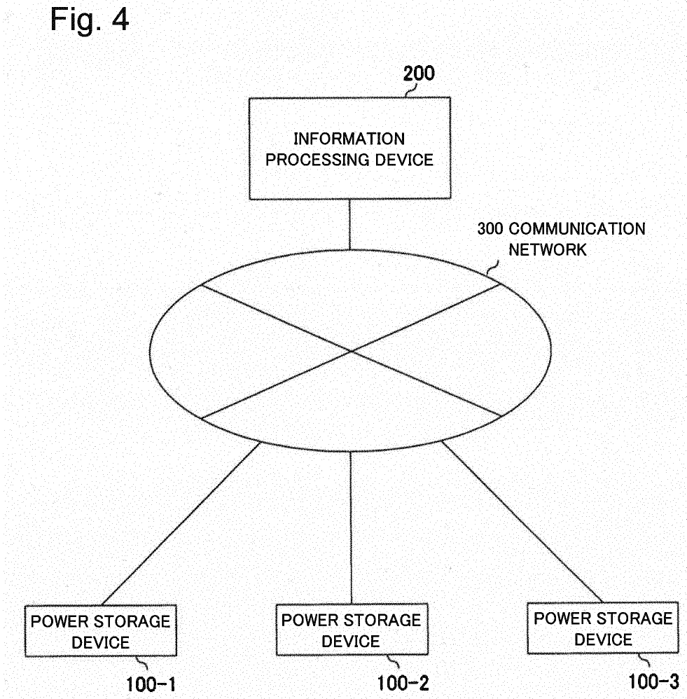

FIG. 4 is a diagram illustrating a first example embodiment using power storage devices of the present invention.

As illustrated in FIG. 4, the present example embodiment includes a plurality of power storage devices 100-1 to 100-3, an information processing device 200, and a communication network 300. Note that, although FIG. 4 is illustrated taking as an example a case where three power storage devices 100-1 to 100-3 are included, the number of power storage devices is not limited to three.

The communication network 300 may be a general communication network, and, through the communication network 300, communication among the power storage devices 100-1 to 100-3 and the information processing device 200 is performed.

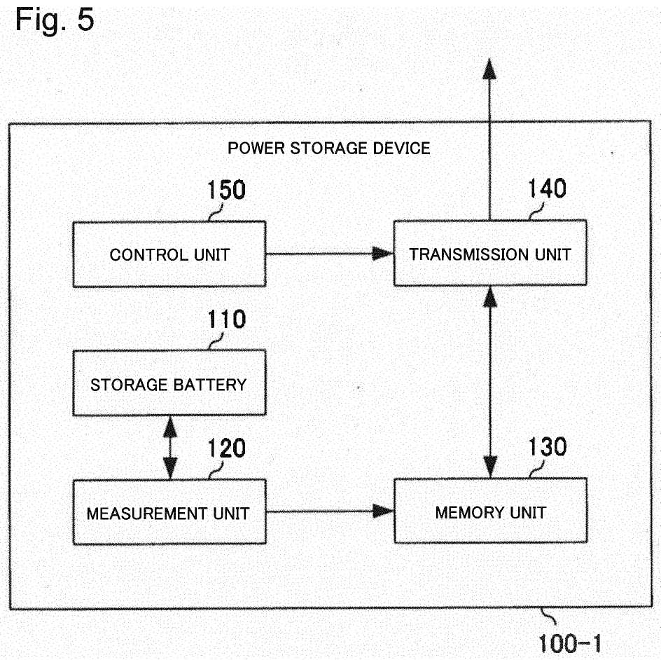

FIG. 5 illustrates an example of an internal configuration of the power storage device 100-1 illustrated in FIG. 4. As illustrated in FIG. 5, the power storage device 100-1 illustrated in FIG. 4 includes a storage battery 110, a measurement unit 120, a memory unit 130, a transmission unit 140, and a control unit 150. Note that, in FIG. 5, an example of principal constituent elements related to the present example embodiment among the constituent elements that the power storage device 100-1 illustrated in FIG. 4 includes is illustrated. In addition, internal configurations of the power storage devices 100-2 and 100-3 illustrated in FIG. 4 may be the same as the internal configuration of the power storage device 100-1.

The storage battery 110 is a secondary battery that can be charged and discharged. The storage battery 110 may be a plurality of battery cells that are connected in series, in parallel, or in series-parallel.

The measurement unit 120 measures a state of the storage battery 110. The state of the storage battery 110 that the measurement unit 120 measures is voltage, current, a state of charge (SOC), temperature, a current integrated value, a total charged/discharged power amount, or the like of the storage battery 110. The measurement unit 120 may measure any one of the measurement items described above or may measure a combination of a plurality of items out of the measurement items described above. A timing at which the measurement unit 120 measures a state of the storage battery 110 may be a preset timing, such as at every certain period.

The memory unit 130 is a database that stores pieces of state data that indicate the states of the storage battery 110 measured by the measurement unit 120 in association with measurement times at which the states were measured.

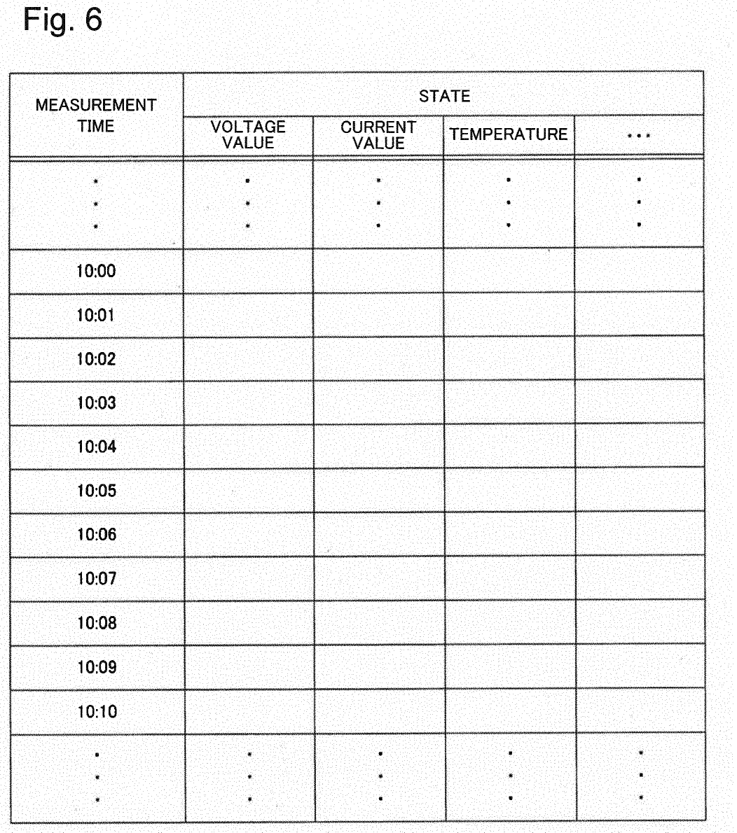

FIG. 6 is a diagram illustrating an example of associations between pieces of state data and measurement times that the memory unit 130 stores. As illustrated in FIG. 6, the memory unit 130 illustrated in FIG. 5 stores a measurement time and a piece of state data, including a plurality of measurement items, that indicates a state of the storage battery 110 measured by the measurement unit 120 at the measurement time in association with each other. FIG. 6 is illustrated taking as an example a case where the measurement unit 120 measures a state of the storage battery 110 every minute.

The transmission unit 140 transmits a piece of state data stored in the memory unit 130 to the communication network 300. The transmission unit 140 may transmit a plurality of pieces of state data at a time among the state data stored in the memory unit 130.

The control unit 150 controls the transmission unit 140 in such a way that each piece of state data transmitted by the transmission unit 140 is a piece of state data the measurement time of which differs each day. The control unit 150 also controls charging and discharging into and from the storage battery 110.

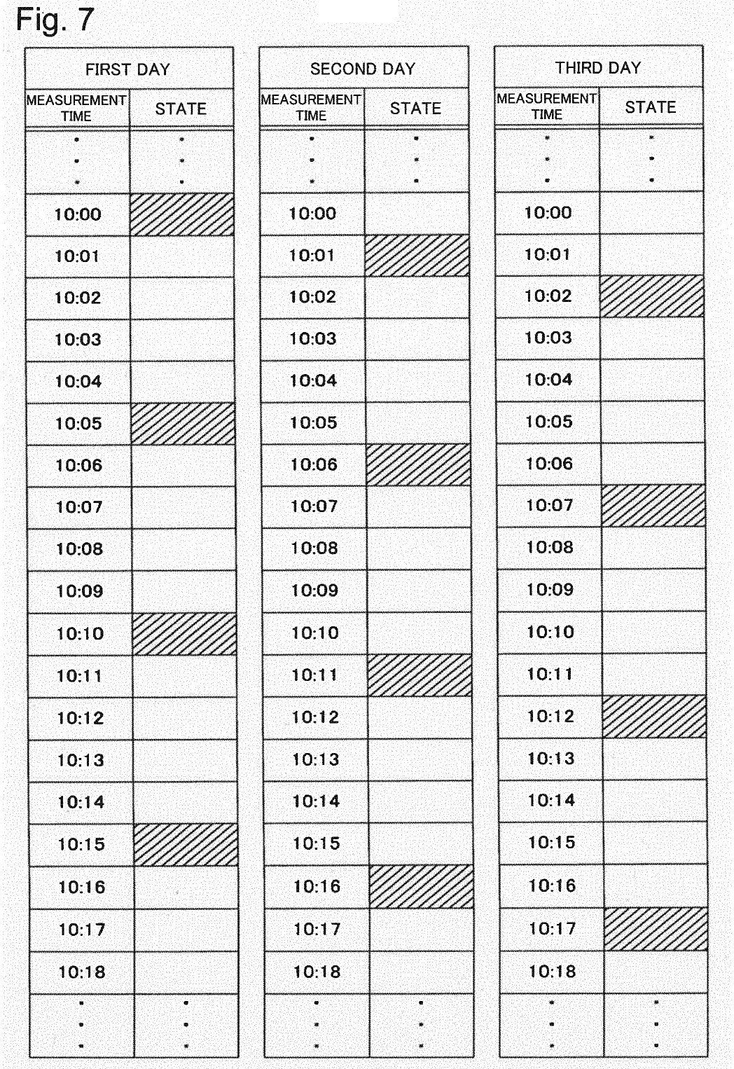

FIG. 7 is a diagram for a description of an example of pieces of state data that the transmission unit 140 transmits. In FIG. 7, pieces of transmission data that the transmission unit 140 transmitted among the pieces of state data illustrated in FIG. 5 are indicated by oblique lines. As illustrated in FIG. 7, the transmission unit 140, on the first day, transmits pieces of state data each of which is associated with a time, at which the piece of state data was measured by the measurement unit 120, of every five minutes starting from 10:00. On the second day, the transmission unit 140 transmits pieces of state data each of which is associated with a time, at which the piece of state data was measured by the measurement unit 120, of every five minutes starting from 10:01. On the third day, the transmission unit 140 transmits pieces of state data each of which is associated with a time, at which the piece of state data was measured by the measurement unit 120, of every five minutes starting from 10:02. In this manner, the control unit 150 controls the transmission unit 140 in such a way that each piece of state data transmitted by the transmission unit 140 is a piece of state data the measurement time of which differs each day. Transmitting pieces of state data in this way and the information processing device 200 superimposing the pieces of state data on one another in accordance with measurement times thereof enable the same result to be obtained as a result obtained in a case where pieces of data from measurement of states at every minute can be collected.

When an actual hardware configuration of the power storage device 100-1 includes a battery management unit (BMU) and a system controller (in the configuration illustrated in FIG. 5, the transmission unit 140 and the control unit 150 are included), the measurement unit 120 included in the BMU measures a state of the storage battery and the memory unit 130 stores measurement data. When the transmission unit 140 is synchronized with the BMU, there are a case where data stored in the memory unit 130 are read and acquired as it is and a case where, after being processed (the data are selected, averaged, and the like), the data are acquired. Therefore, the transmission unit 140 is required to acquire data at a timing in accordance with the cases. It is needless to say that there is a possibility that the order of priority is determined in accordance with another factor. The same applies to example embodiments that will be described below.

The power storage device 100-1 has switches for performing cell balancing operation on an as-needed basis and cutting-off input/output power on an as-needed basis.

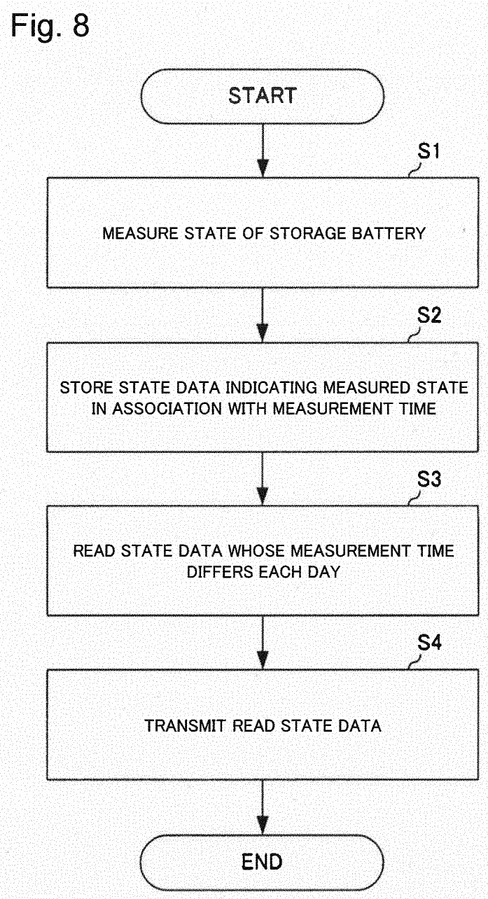

A reporting method in the power storage device 100-1 illustrated in FIG. 5 will be described below. FIG. 8 is a flowchart for a description of an example of the reporting method in the power storage device 100-1 illustrated in FIG. 5.

First, the measurement unit 120 measures a state of the storage battery 110 (step S1). Next, the memory unit 130 stores a piece of state data that indicates the state of the storage battery measured by the measurement unit 120 in association with a measurement time at which the state was measured (step S2).

Subsequently, the transmission unit 140, in accordance with control by the control unit 150, reads a piece of state data the measurement time of which differs each day from the memory unit 130 (step S3). Next, the transmission unit 140 transmits the read piece of state data to the information processing device 200 (step S4). On this occasion, the transmission unit 140 transmits, in conjunction with the piece of state data, a measurement time that has been stored associated with the piece of state data to the information processing device 200.

The information processing device 200, based on the pieces of state data on each storage battery that were transmitted from one of the power storage devices 100-1 to 100-3, estimates a deterioration state of the storage battery. The information processing device 200 may be a server device, a general personal computer (PC), or a mobile communication terminal and is required to be a device provided with functions of performing communication and predetermined processing.

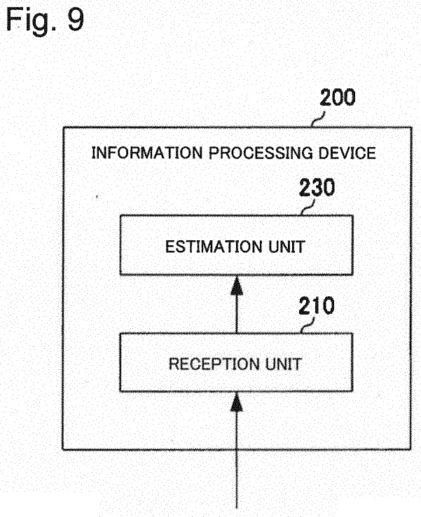

FIG. 9 illustrates an example of an internal configuration of the information processing device 200 illustrated in FIG. 4. As illustrated in FIG. 9, the information processing device 200 illustrated in FIG. 4 includes a reception unit 210 and an estimation unit 230. Note that, in FIG. 9, an example of principal constituent elements related to the present example embodiment among the constituent elements that the information processing device 200 illustrated in FIG. 4 includes is illustrated.

The reception unit 210 receives a plurality of pieces of state data that are transmitted from each of the power storage devices 100-1 to 100-3 and that indicate states of the storage battery that the power storage device, of the power storage devices 100-1 to 100-3, includes.

The estimation unit 230 estimates a deterioration state of each storage battery, based on the states that the plurality of pieces of state data received by the reception unit 210 indicate. Specifically, the estimation units 230 superimposes the pieces of state data that were received by the reception unit 210 and each of which corresponds to a different measurement time each day on one another in accordance with measurement times of the pieces of state data and estimates a deterioration state of the storage battery, based on a result of the superimposition.

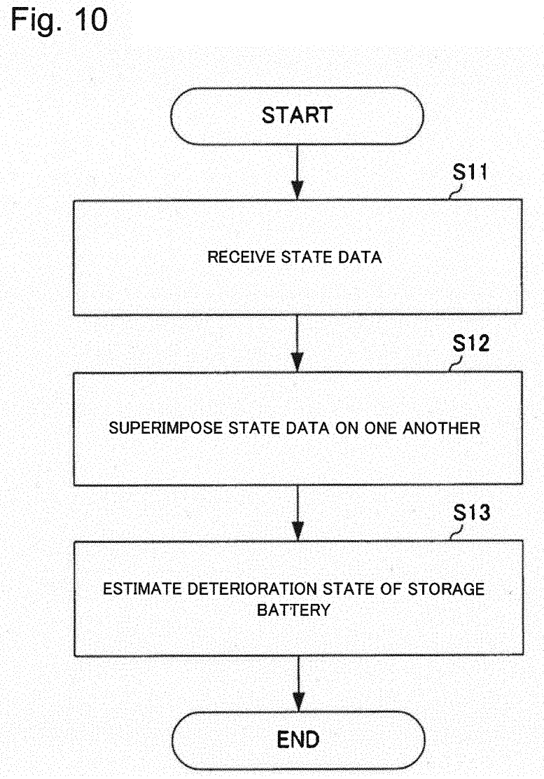

An estimation method in the information processing device 200 illustrated in FIG. 9 will be described below. FIG. 10 is a flowchart for a description of an example of the estimation method in the information processing device 200 illustrated in FIG. 9.

When pieces of state data of a storage battery are transmitted from each of the power storage devices 100-1 to 100-3, the reception unit 210 receives the pieces of state data (step S11). The estimation unit 230 superimposes the pieces of state data that were received by the reception unit 210 and each of which corresponds to a different measurement time each day on one another in accordance with measurement times of the pieces of state data (step S12).

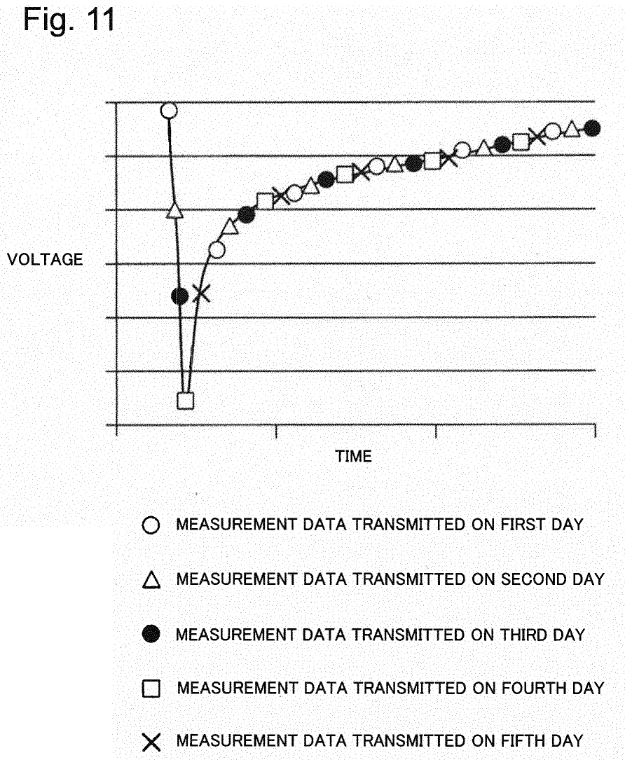

FIG. 11 is a diagram illustrating an example of a result of superimposition of pieces of state data on one another by the estimation unit 230 illustrated in FIG. 9. As illustrated in FIG. 11, the estimation unit 230 superimposes pieces of state data (measurement data) transmitted on the first to fifth days on one another in accordance with time. The measurement times of the pieces of measurement data transmitted from each of the power storage devices 100-1 to 100-3 are shifted each day. For this reason, even when pieces of data the measurement intervals of which on a daily basis are wide are available, superimposing such pieces of data for days on one another causes measurement intervals thereof to be narrowed.

The estimation unit 230 estimates a deterioration state of each storage battery, using the superimposed pieces of state data (step S13). The estimation unit 230 may estimate that deterioration of the storage battery has progressed when voltage of the storage battery in a fully-charged state that the superimposed pieces of state data indicate is lower than a predetermined threshold value. Alternatively, the estimation unit 230 may estimate that deterioration of the storage battery has progressed when a rate (inclination) of decrease in capacity of the storage battery in accordance with elapsed days is greater than a normal value, when change in temperature of the storage battery is large, or the like, and a determination condition is not specified specifically herein.

In order to collect a sufficient amount of data in a period of time in which an instantaneous response occurs, a sampling interval may be set to be short. In order to constantly collect a lot of data, it is required to secure sufficient operation speed of a central processing unit (CPU) and a sufficient amount of memory on the control system side, which causes a hardware cost to increase.

Thus, as in the present example embodiment, pieces of state data of a storage battery that each of the power storage devices 100-1 to 100-3 transmits to the information processing device 200 in a day are offset by a predetermined time interval each day for a predetermined period (for example, a week). That is, pieces of state data of a storage battery that each of the power storage devices 100-1 to 100-3 transmits to the information processing device 200 in a day are configured to be pieces of state data at measurement times that are shifted each day. The information processing device 200 superimposes the transmitted pieces of state data on one another in accordance with time. This configuration enables precise data to be obtained even when the amount of data transmitted per day is set to be small in order to reduce a load on the information processing device.

### Second Example Embodiment

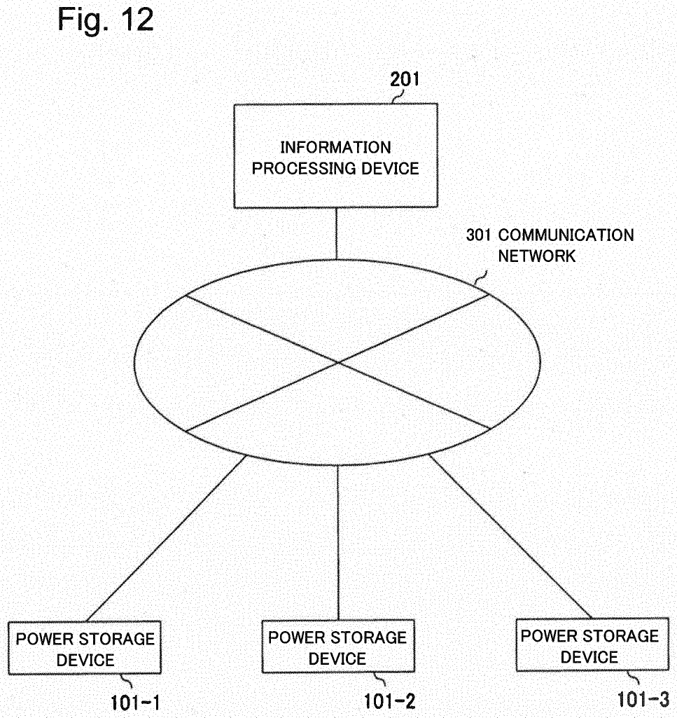

FIG. 12 is a diagram illustrating a second example embodiment (a power storage system) using power storage devices of the present invention.

As illustrated in FIG. 12, the present example embodiment includes a plurality of power storage devices 101-1 to 101-3, an information processing device 201, and a communication network 301. Note that, although FIG. 12 is illustrated taking as an example a case where three power storage devices 101-1 to 101-3 are included, the number of power storage devices is not limited to three.

The communication network 301 may be a general communication network, and, through the communication network 301, communication among the power storage devices 101-1 to 101-3 and the information processing device 201 is performed.

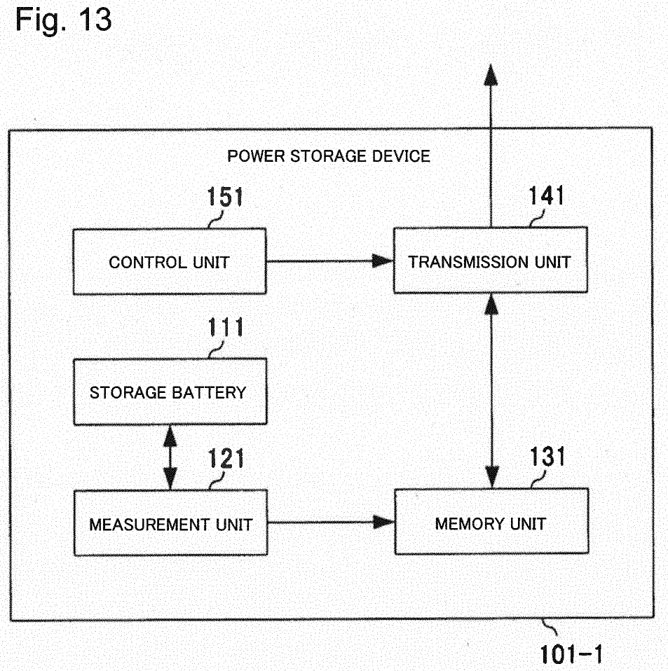

FIG. 13 is a diagram illustrating an example of an internal configuration of the power storage device 101-1 illustrated in FIG. 12. As illustrated in FIG. 13, the power storage device 101-1 illustrated in FIG. 12 includes a storage battery 111, a measurement unit 121, a memory unit 131, a transmission unit 141, and a control unit 151. Note that, in FIG. 13, an example of principal constituent elements related to the present example embodiment among the constituent elements that the power storage device 101-1 illustrated in FIG. 12 includes is illustrated. In addition, internal configurations of the power storage devices 101-2 and 101-3 illustrated in FIG. 12 may be the same as the internal configuration of the power storage device 101-1.

The storage battery 111 is a secondary battery that can be charged and discharged. The storage battery 111 may be a plurality of battery cells that are connected in series, in parallel, or in series-parallel.

The measurement unit 121 measures a state of the storage battery 111. The state of the storage battery 111 that the measurement unit 121 measures is voltage, current, an SOC, temperature, a current integrated value, a total charged/discharged power amount, or the like of the storage battery 111. The measurement unit 121 may measure any one of the measurement items described above or may measure a combination of a plurality of items out of the measurement items described above. A timing at which the measurement unit 121 measures a state of the storage battery 111 may be a preset timing, such as at every certain period.

The memory unit 131 is a database that stores pieces of state data that indicate the states of the storage battery 111 measured by the measurement unit 121 in association with measurement times at which the states were measured. The associations are the same as those in the first example embodiment.

The transmission unit 141 transmits a piece of state data stored in the memory unit 131 to the communication network 301. The transmission unit 141 may transmit a plurality of pieces of state data at a time among the state data stored in the memory unit 131.

The control unit 151 controls a timing at which the transmission unit 141 transmits a piece of state data. Specifically, the control unit 151 controls a transmission timing in such a way that the transmission unit 141 transmits a piece of state data to the information processing device 201 at a timing that is mutually different from timings at which the power storage devices 101-2 and 101-3, which are power storage devices other than the power storage device 101-1 among the power storage devices 101-1 to 101-3, respectively transmit pieces of state data. The control unit 151 may rotate a transmission timing at which the transmission unit 141 transmits a piece of state data among the power storage devices 101-1 to 101-3 each day. When the information processing device 201 notifies each of the power storage devices 101-1 to 101-3 of a transmission timing, the control unit 151 of the power storage device performs control in such a way that the transmission unit 141 of the power storage device transmits a piece of state data at the notified transmission timing. The control unit 151 controls charging and discharging into and from the storage battery 111.

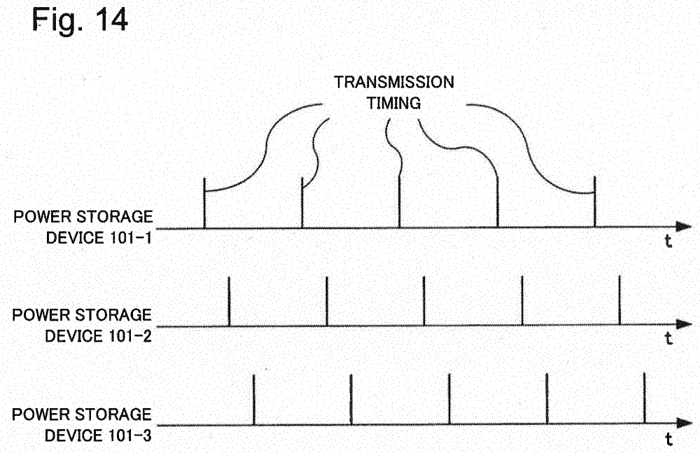

FIG. 14 is a diagram illustrating an example of transmission timings of pieces of state data from the power storage devices 101-1 to 101-3 that are controlled by the control unit 151 illustrated in FIG. 13. As illustrated in FIG. 14, timings at which pieces of state data are transmitted from the power storage device 101-1 are different from timings at which pieces of state data are transmitted from the other power storage devices 101-2 and 101-3. In addition, timings at which pieces of state data are transmitted from the power storage device 101-2 are different from timings at which pieces of state data are transmitted from the other power storage devices 101-1 and 101-3. Further, timings at which pieces of state data are transmitted from the power storage device 101-3 are different from timings at which pieces of state data are transmitted from the other power storage devices 101-1 and 101-2.

The power storage device 101-1 has switches for performing cell balancing operation on an as-needed basis and cutting-off input/output power on an as-needed basis.

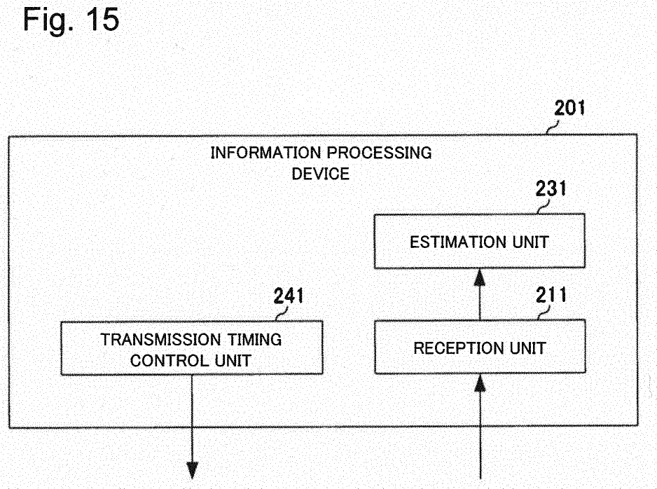

FIG. 15 illustrates an example of an internal configuration of the information processing device 201 illustrated in FIG. 12. As illustrated in FIG. 15, the information processing device 201 illustrated in FIG. 12 includes a reception unit 211, an estimation unit 231, and a transmission timing control unit 241. Note that, in FIG. 15, an example of principal constituent elements related to the present example embodiment among the constituent elements that the information processing device 201 illustrated in FIG. 12 includes is illustrated.

The reception unit 211 receives a plurality of pieces of state data that are transmitted from the power storage devices 101-1 to 101-3 and that indicate states of storage batteries that the power storage devices 101-1 to 101-3 include.

The estimation unit 231 estimates a deterioration state of each storage battery, based on the states that the plurality of pieces of state data received by the reception unit 211 indicate. Specifically, the estimation units 231 superimposes pieces of state data that were transmitted from each of the power storage devices 101-1 to 101-3 and that were received by the reception unit 211 on one another in accordance with measurement times and estimates a deterioration state of the storage battery, based on a result of the superimposition.

The transmission timing control unit 241 notifies each of the power storage devices 101-1 to 101-3 of a transmission timing that is mutually different from transmission timings for the power storage devices other than the power storage device among the power storage devices 101-1 to 101-3.

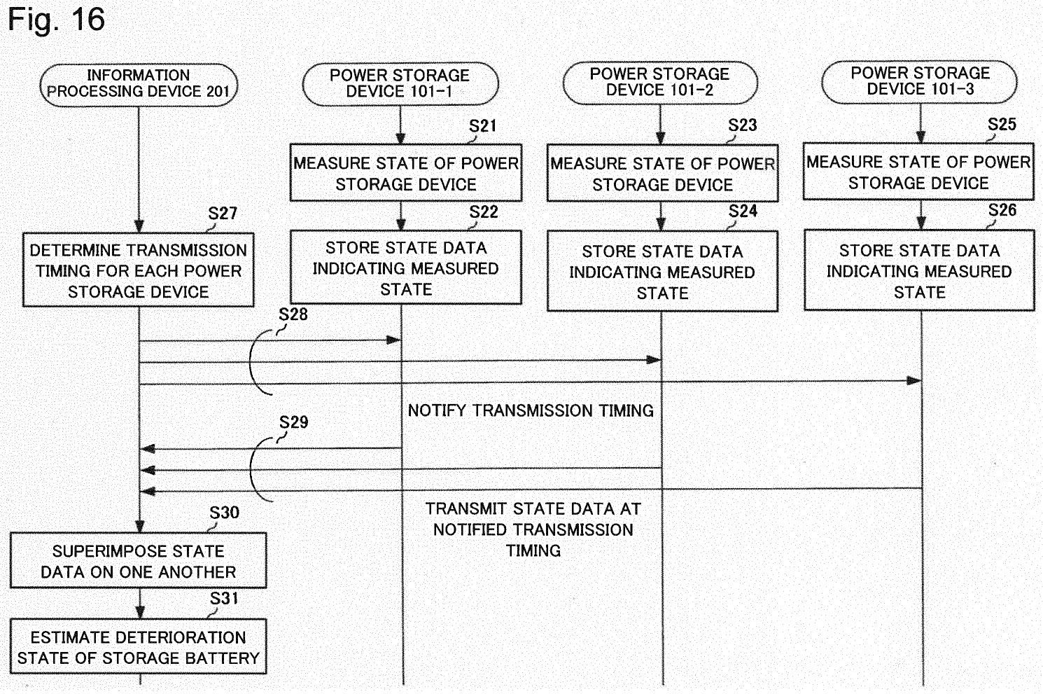

A reporting method in the power storage system illustrated in FIG. 12 will be described below. FIG. 16 is a sequence diagram for a description of an example of the estimation method in the power storage system illustrated in FIG. 12. The following description will be made taking as an example a case where the transmission timing control unit 241 of the information processing device 201 determines transmission timings at which pieces of state data are transmitted from the power storage devices 101-1 to 101-3.

First, the measurement unit 121 of the power storage device 101-1 measures a state of the storage battery 111 of the power storage device 101-1 (step S21). Next, the memory unit 131 of the power storage device 101-1 stores a piece of state data that indicates the state of the storage battery measured by the measurement unit 121 of the power storage device 101-1 in association with a measurement time at which the state was measured (step S22). Similarly, the measurement unit 121 of the power storage device 101-2 measures a state of the storage battery 111 of the power storage device 101-2 (step S23). Next, the memory unit 131 of the power storage device 101-2 stores a piece of state data that indicates the state of the storage battery measured by the measurement unit 121 of the power storage device 101-2 in association with a measurement time at which the state was measured (step S24). Similarly, the measurement unit 121 of the power storage device 101-3 measures a state of the storage battery 111 of the power storage device 101-3 (step S25). Next, the memory unit 131 of the power storage device 101-3 stores a piece of state data that indicates the state of the storage battery measured by the measurement unit 121 of the power storage device 101-3 in association with a measurement time at which the state was measured (step S26).

The transmission timing control unit 241 of the information processing device 201 determines a transmission timing at which a piece of state data is transmitted from each of the power storage devices 101-1 to 101-3 (step S27). In this step, the transmission timing control unit 241 determines a transmission timing for each of the power storage devices 101-1 to 101-3 in such a way that the transmission timings of pieces of state data from the respective power storage devices 101-1 to 101-3 do not coincide with one another. The transmission timing control unit 241 may, for example, rotate a transmission sequence on a daily basis among the power storage devices 101-1 to 101-3, such as setting a transmission sequence of pieces of state data on a first day as from the power storage device 101-1 to the power storage device 101-2 to the power storage device 101-3, a transmission sequence on the next day as from the power storage device 101-2 to the power storage device 101-3 to the power storage device 101-1, and a transmission sequence on the day after the next day as the power storage device 101-3 to the power storage device 101-1 to the power storage device 101-2. Subsequently, the transmission timing control unit 241 notifies the power storage devices 101-1 to 101-3 of the determined transmission timings (step S28).

Subsequently, the transmission unit 141 of each of the power storage devices 101-1 to 101-3 reads a piece of state data from the memory unit 131 and transmits the read piece of state data to the information processing device 201 at the timing notified by the information processing device 201 (step S29).

When the reception unit 211 of the information processing device 201 receives pieces of state data transmitted from each of the power storage devices 101-1 to 101-3, the estimation unit 231 superimposes the pieces of state data received by the reception unit 211 on one another in accordance with measurement times (step S30). Subsequently, the estimation unit 231 estimates a deterioration state of each storage battery, based on a result of the superimposition (step S31).

In this way, the power storage devices 101-1 to 101-3 transmit pieces of state data indicating states of the storage batteries to the information processing device 201 at transmission timings different from one another. This configuration enables congestion in the communication network 301 to be prevented from occurring.

### Third Example Embodiment

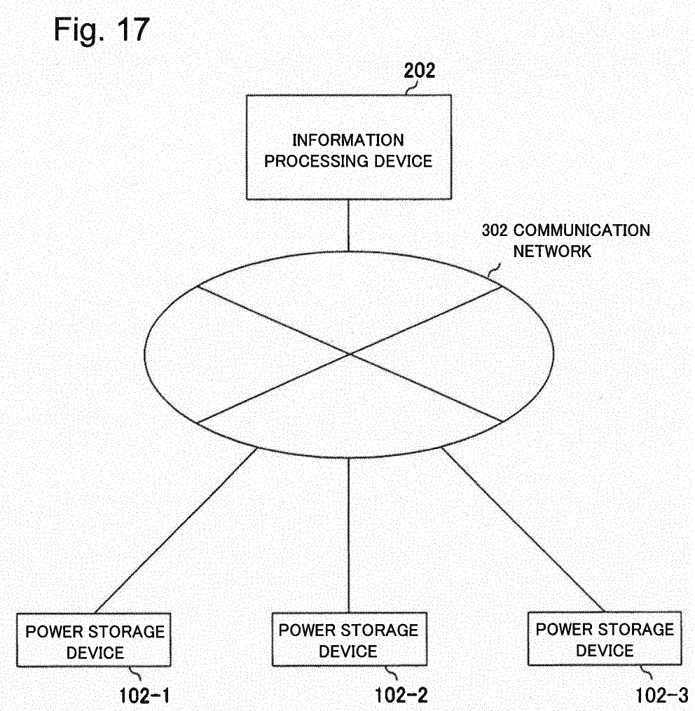

FIG. 17 is a diagram illustrating a third example embodiment using power storage devices of the present invention.

As illustrated in FIG. 17, the present example embodiment includes a plurality of power storage devices 102-1 to 102-3, an information processing device 202, and a communication network 302. Note that, although FIG. 17 is illustrated taking as an example a case where three power storage devices 102-1 to 102-3 are included, the number of power storage devices is not limited to three.

Each of the power storage devices 102-1 to 102-3 includes a storage battery, measures a state of the storage battery, and transmits a measurement result as a piece of state data to the information processing device 202 via the communication network 302. Each of the power storage devices 102-1 to 102-3 has switches for performing cell balancing operation on an as-needed basis and cutting-off input/output power on an as-needed basis.

The communication network 302 may be a general communication network, and, through the communication network 302, communication among the power storage devices 102-1 to 102-3 and the information processing device 202 is performed.

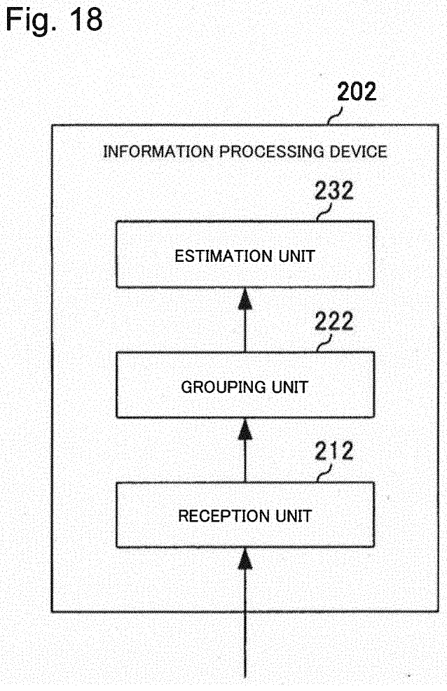

FIG. 18 illustrates an example of an internal configuration of the information processing device 202 illustrated in FIG. 17. As illustrated in FIG. 18, the information processing device 202 illustrated in FIG. 17 includes a reception unit 212, a grouping unit 222, and an estimation unit 232. Note that, in FIG. 18, an example of principal constituent elements related to the present example embodiment among the constituent elements that the information processing device 202 illustrated in FIG. 17 includes is illustrated.

The reception unit 212 receives a plurality of sets of pieces of state data that are transmitted from the power storage devices 102-1 to 102-3 and that indicate states of the storage batteries that the power storage devices 102-1 to 102-3 include.

The grouping unit 222 groups the plurality of power storage devices 102-1 to 102-3 into a group(s). Grouping methods for the grouping include, for example, grouping based on areas where the power storage devices 102-1 to 102-3 are placed, grouping based on placement times when the power storage devices 102-1 to 102-3 were placed, grouping based on whether or not each of the power storage devices 102-1 to 102-3 includes a plurality of storage batteries, grouping based on an operation method of the power storage devices 102-1 to 102-3 (for back-up use to constantly secure a certain amount of power, for peak cut operation during sunlit hours or daytime in a cooperative operation with photovoltaic power generation, and the like), and grouping based on whether or not manufacturers of the power storage devices 102-1 to 102-3 are the same.

The estimation unit 232, with respect to each group grouped by the grouping unit 222, estimates a deterioration state of the storage battery(ies), based on states that a set(s) of pieces of state data received by the reception unit 212 indicate. Specifically, the estimation units 232, with respect to each group grouped by the grouping unit 222, superimposes states that, among the sets of pieces of state data that were transmitted from the power storage devices 102-1 to 102-3 and that were received by the reception unit 212, a set(s) of pieces of state data from a power storage device(s) belonging to the group indicate on one another in accordance with measurement times and estimates a deterioration state of the storage battery(ies), based on a result of the superimposition.

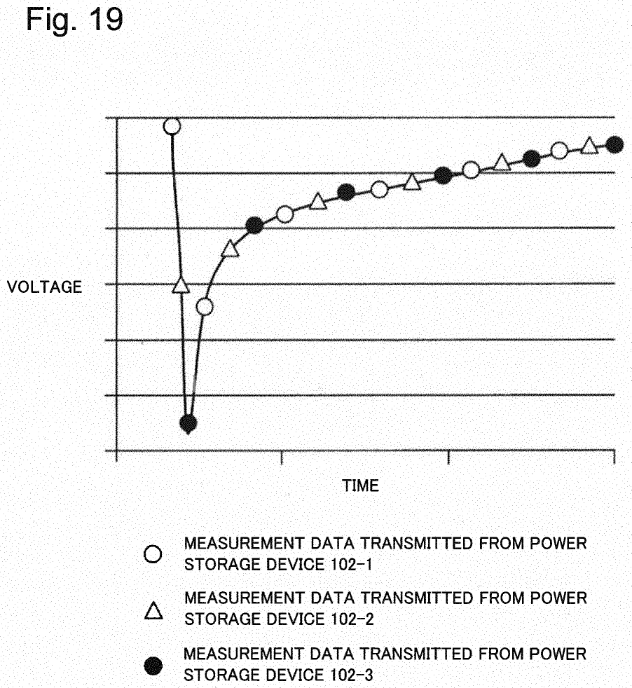

FIG. 19 is a diagram illustrating an example of a result of superimposition of sets of pieces of state data (measurement data) transmitted from the power storage devices 102-1 to 102-3 on one another by the estimation unit 232 illustrated in FIG. 18. FIG. 19 is illustrated taking as an example a case where the grouping unit 222 groups the power storage devices 102-1 to 102-3 into a group.

As illustrated in FIG. 19, voltage values in the measurement data transmitted from the power storage device 102-1, voltage values in the measurement data transmitted from the power storage device 102-2, and voltage values in the measurement data transmitted from the power storage device 102-3 are merged in accordance with measurement times.

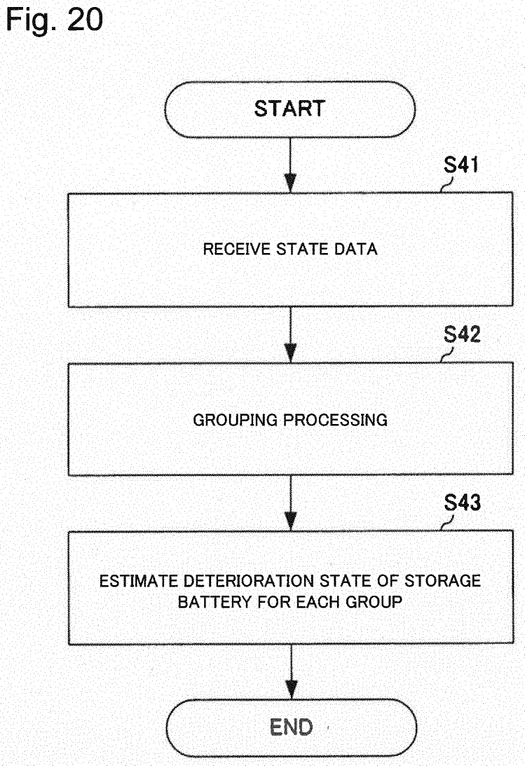

An estimation method in the information processing device 202 illustrated in FIG. 18 will be described below. FIG. 20 is a flowchart for a description of the estimation method in the information processing device 202 illustrated in FIG. 18.

When sets of pieces of state data of the storage batteries are transmitted from the power storage devices 102-1 to 102-3, the reception unit 212 receives the sets of pieces of state data (step S41). The grouping unit 222 groups the power storage devices 102-1 to 102-3 into a group(s). Since it is assumed that the power storage devices 102-1 to 102-3 belong to one group, the grouping unit 222 groups the sets of pieces of state data received by the reception unit 212 into a group (step S42).

Subsequently, the estimation unit 232, with respect to each group grouped by the grouping unit 222, superimposes states that a set(s) of pieces of state data received by the reception unit 212 indicate on one another in accordance with measurement times and estimates a deterioration state of the storage battery(ies), based on a result of the superimposition (step S43). The estimation method may be a method of estimating that deterioration of the storage battery(ies) has progressed when a result of the superimposition shows that a voltage value(s) of the fully-charged storage battery(ies) is/are lower than a predetermined threshold value, when a rate (inclination) of decrease in capacity of the storage battery(ies) in accordance with elapsed days is greater than a normal value, when change in temperature of the storage battery(ies) is substantial, or the like, and a determination condition is not specified specifically herein.

Grouping pieces of state data transmitted from power storage devices into a predetermined group(s) and superimposing pieces of state data on one another with respect to each group in this manner enables precise data to be obtained even when the amount of data to be transmitted is small for each storage battery.

### Fourth Example Embodiment

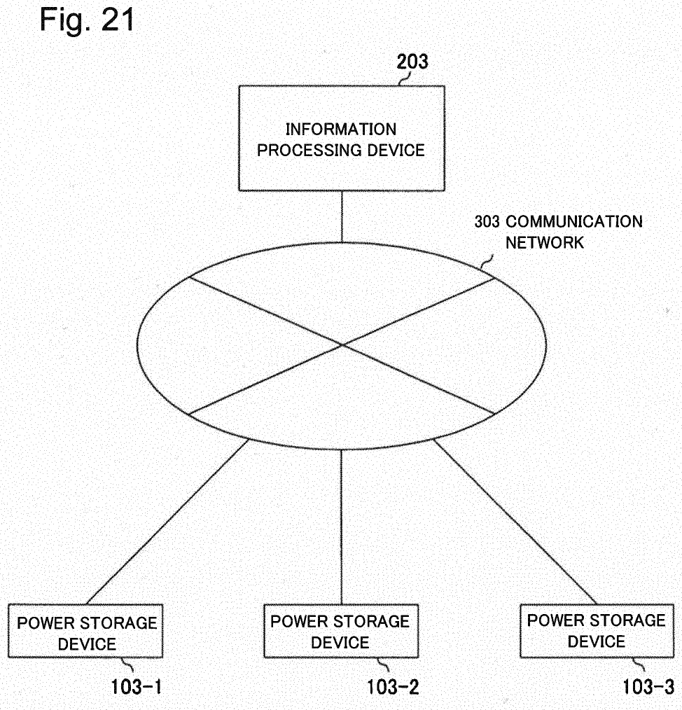

FIG. 21 is a diagram illustrating a fourth example embodiment using power storage devices of the present invention.

As illustrated in FIG. 21, the present example embodiment includes a plurality of power storage devices 103-1 to 103-3, an information processing device 203, and a communication network 303. Note that, although FIG. 21 is illustrated taking as an example a case where three power storage devices 103-1 to 103-3 are included, the number of power storage devices is not limited to three.

The communication network 303 may be a general communication network, and, through the communication network 302, communication among the power storage devices 103-1 to 103-3 and the information processing device 203 is performed.

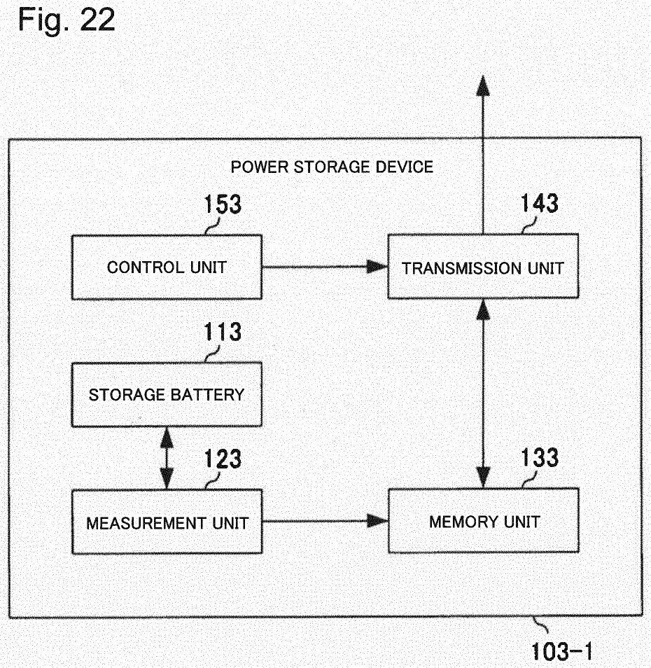

FIG. 22 illustrates an example of an internal configuration of the power storage device 103-1 illustrated in FIG. 21. As illustrated in FIG. 22, the power storage device 103-1 illustrated in FIG. 21 includes a storage battery 113, a measurement unit 123, a memory unit 133, a transmission unit 143, and a control unit 153. Note that, in FIG. 22, an example of principal constituent elements related to the present example embodiment among the constituent elements that the power storage device 103-1 illustrated in FIG. 21 includes is illustrated. In addition, internal configurations of the power storage devices 103-2 and 103-3 illustrated in FIG. 21 may be the same as the internal configuration of the power storage device 103-1.

The storage battery 113 is a secondary battery that can be charged and discharged. The storage battery 113 may be a plurality of battery cells that are connected in series, in parallel, or in series-parallel.

The measurement unit 123 measures a state of the storage battery 113. The state of the storage battery 113 that the measurement unit 123 measures is voltage, current, an SOC, temperature, a current integrated value, a total charged/discharged power amount, or the like of the storage battery 113. The measurement unit 123 may measure any one of the measurement items described above or may measure a combination of a plurality of items out of the measurement items described above. A timing at which the measurement unit 123 measures a state of the storage battery 113 may be a preset timing, such as at every certain period.

The memory unit 133 is a database that stores pieces of state data that indicate the states of the storage battery 113 measured by the measurement unit 123 in association with measurement times at which the states were measured. A form of storage in the memory unit 133 may be the same as that in the first example embodiment.

The transmission unit 143 transmits a piece of state data stored in the memory unit 133 to the communication network 303. The transmission unit 143 may transmit a plurality of pieces of state data at a time among the state data stored in the memory unit 133.

The control unit 153 controls transmission of pieces of state data from the transmission unit 143. Specifically, the control unit 153 controls the transmission unit 143 in such a way that pieces of state data transmitted by the transmission unit 143 are set to be pieces of state data the measurement times of which are included in a period on a daily basis. In addition, the control unit 153 sets such periods, which are set on a daily basis, in such a way that the periods set for a plurality of days have portions that overlap each other. The control unit 153 controls charging and discharging into and from the storage battery 113.

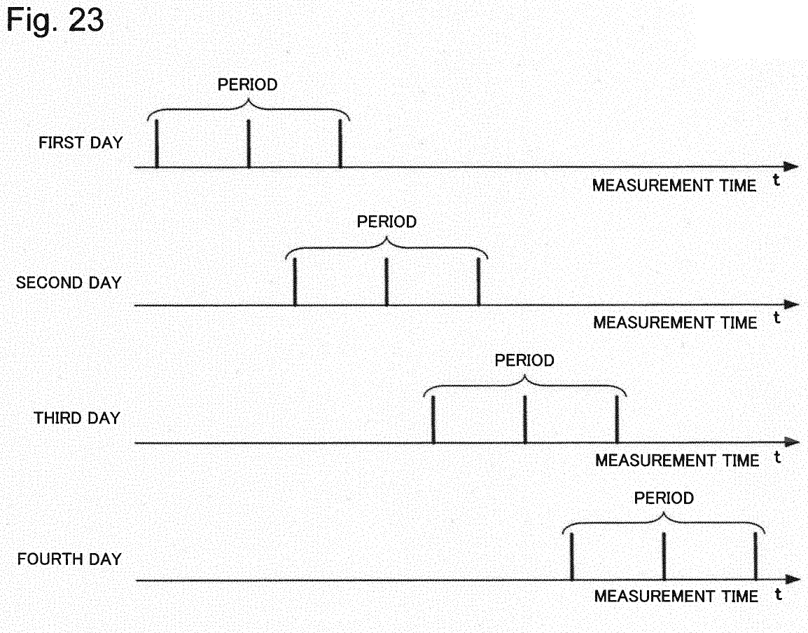

FIG. 23 is a diagram for a description of an example of transmission timings of pieces of state data that the transmission unit 143 transmits and the transmission of which is controlled by the control unit 153 illustrated in FIG. 22. In FIG. 23, pieces of state data that the transmission unit 143 transmits and the transmission of which is controlled by the control unit 153 are illustrated by thick lines. As illustrated in FIG. 23, the transmission is controlled in such a way that a portion of a period including measurement times of pieces of state data that the transmission unit 143 transmits on a first day and a portion of a period including measurement times of pieces of state data that the transmission unit 143 transmits on a second day overlap each other. In addition, the transmission is also controlled in such a way that a portion of the period including the measurement times of the pieces of state data that the transmission unit 143 transmits on the second day and a portion of a period including measurement times of pieces of state data that the transmission unit 143 transmits on a third day overlap each other. Further, the transmission is also controlled in such a way that a portion of the period including the measurement times of the pieces of state data that the transmission unit 143 transmits on the third day and a portion of a period including measurement times of pieces of state data that the transmission unit 143 transmits on a fourth day overlap each other.

The power storage device 103-1 has switches for performing cell balancing operation on an as-needed basis and cutting-off input/output power on an as-needed basis.

The information processing device 203, based on pieces of state data of each storage battery that are transmitted from one of the power storage devices 103-1 to 103-3, estimates a deterioration state of the storage battery. The information processing device 203 may be a server device, a general PC, or a mobile communication terminal and is required to be a device provided with functions of performing communication and predetermined processing. Constituent elements that the information processing device 203 includes and operation thereof may be the same as those in the first example embodiment.

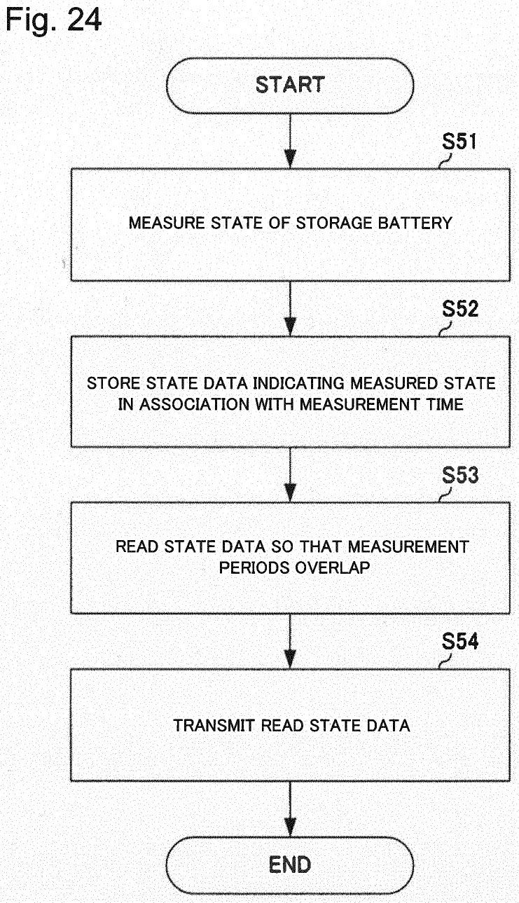

A reporting method in the power storage device 103-1 illustrated in FIG. 22 will be described below. FIG. 24 is a flowchart for a description of an example of the reporting method in the power storage device 103-1 illustrated in FIG. 22.

First, the measurement unit 123 measures a state of the storage battery 113 (step S51). Next, the memory unit 133 stores a piece of state data that indicates the state of the storage battery measured by the measurement unit 123 in association with a measurement time at which the state was measured (step S52).

Next, the control unit 153 sets periods that are set on a daily basis in such a way that the periods set for a plurality of days have portions that overlap each other and controls the transmission unit 143 on a daily basis in such a way that pieces of state data transmitted are pieces of state data the measurement times of which are included in a period set for the day. The transmission unit 143, in accordance with control by the control unit 153, reads a piece of state data from the memory unit 133 (step S53). Next, the transmission unit 143 transmits the read piece of state data to the information processing device 203 (step S54).

In this way, each of the power storage devices 103-1 to 103-3 performs control in such a way that pieces of state data to be transmitted to the information processing device 203 in a day are set to be pieces of state data included in one of measurement periods that are shifted each day and the measurement periods for a plurality of days have portions that overlap each other. The information processing device 203 superimposes pieces of state data transmitted from each storage battery on one another in accordance with time. This configuration enables precise data to be obtained even when the amount of data transmitted per day is set to be small in order to reduce a load on the information processing device.

### Fifth Example Embodiment

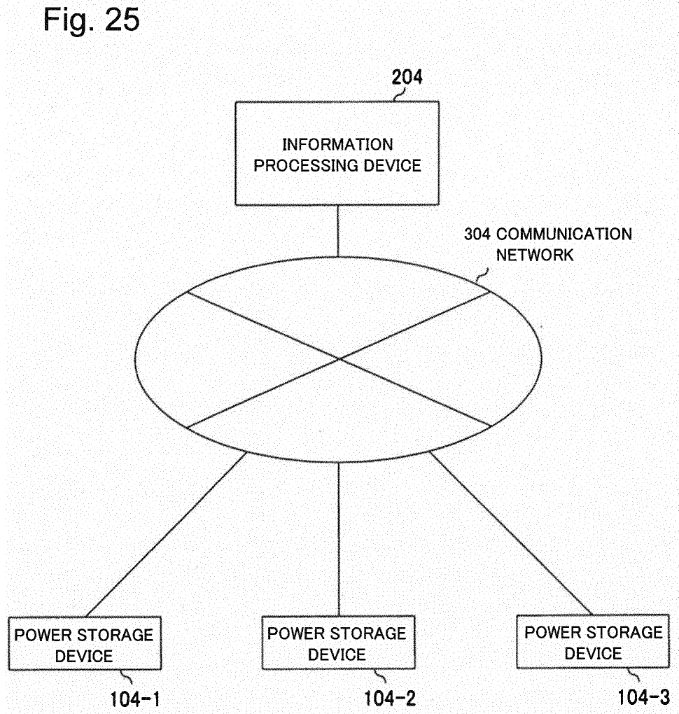

FIG. 25 is a diagram illustrating a fifth example embodiment using power storage devices of the present invention.

As illustrated in FIG. 25, the present example embodiment includes a plurality of power storage devices 104-1 to 104-3, an information processing device 204, and a communication network 304. Note that, although FIG. 25 is illustrated taking as an example a case where three power storage devices 104-1 to 104-3 are included, the number of power storage devices is not limited to three.

The communication network 304 may be a general communication network, and, through the communication network 304, communication among the power storage devices 104-1 to 104-3 and the information processing device 204 is performed.

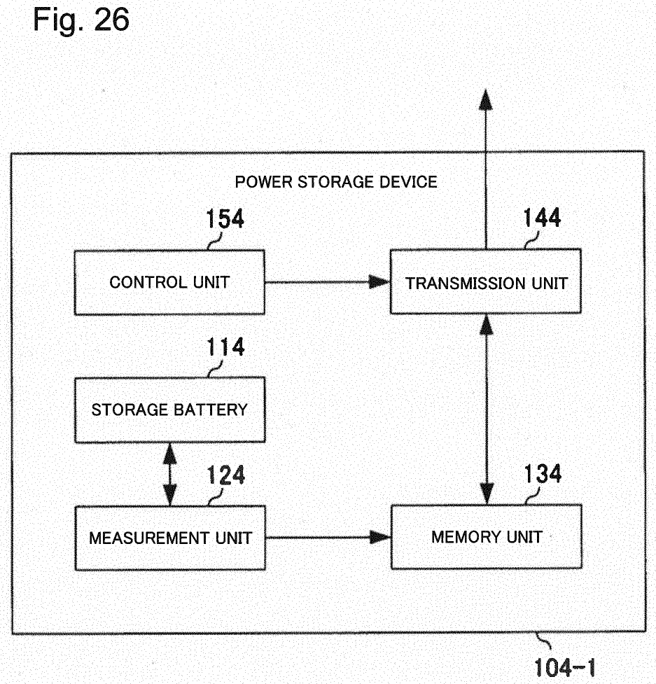

FIG. 26 illustrates an example of an internal configuration of the power storage device 104-1 illustrated in FIG. 25. As illustrated in FIG. 26, the power storage device 104-1 illustrated in FIG. 25 includes a storage battery 114, a measurement unit 124, a memory unit 134, a transmission unit 144, and a control unit 154. Note that, in FIG. 26, an example of principal constituent elements related to the present example embodiment among the constituent elements that the power storage device 104-1 illustrated in FIG. 25 includes is illustrated. In addition, internal configurations of the power storage devices 104-2 and 104-3 illustrated in FIG. 25 may be the same as the internal configuration of the power storage device 104-1.

The storage battery 114 is a secondary battery that can be charged and discharged. The storage battery 114 may be a plurality of battery cells that are connected in series, in parallel, or in series-parallel.

The measurement unit 124 measures a state of the storage battery 114. The state of the storage battery 114 that the measurement unit 124 measures is voltage, current, an SOC, temperature, a current integrated value, a total charged/discharged power amount, or the like of the storage battery 114. The measurement unit 124 may measure any one of the measurement items described above or may measure a combination of a plurality of items out of the measurement items described above. A timing at which the measurement unit 124 measures a state of the storage battery 114 may be a preset timing, such as at every certain period.

The memory unit 134 is a database that stores pieces of state data that indicate the states of the storage battery 114 measured by the measurement unit 124 in association with measurement times at which the states were measured. A form of storage in the memory unit 134 may be the same as that in the first example embodiment.

The transmission unit 144 transmits a piece of state data stored in the memory unit 134 to the communication network 304. The transmission unit 144 may transmit a plurality of pieces of state data at a time among the state data stored in the memory unit 134.

The control unit 154 controls the transmission unit 144 in such a way that intervals between adjacent measurement times of pieces of state data transmitted by the transmission unit 144 change depending on time. Specifically, the control unit 154 makes intervals between adjacent measurement times during a predetermined period around a charge start time, a predetermined period around a charge end time, a predetermined period around a discharge start time, and a predetermined period around a discharge end time of the storage battery 114 narrower than intervals between adjacent measurement times during the other periods. The predetermined periods are periods that are set in advance and can be changed. The control unit 154 controls charging and discharging into and from the storage battery 114.

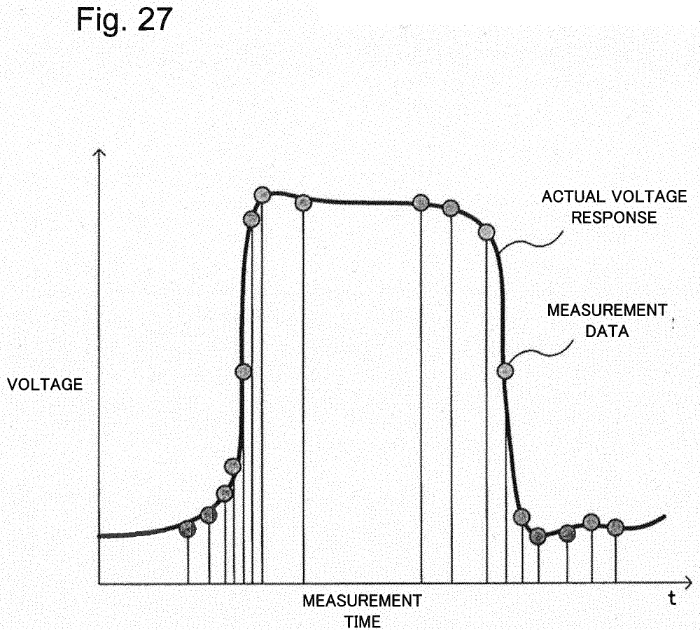

FIG. 27 is a diagram for a description of an example of pieces of state data that the transmission unit 144 transmits and the transmission of which is controlled by the control unit 154 illustrated in FIG. 26. In FIG. 27, pieces of state data that the transmission unit 144 transmits and the transmission of which is controlled by the control unit 154 are illustrated by circles. As illustrated in FIG. 27, intervals between measurement times of pieces of state data to be transmitted around the charge start time, around the charge end time, around the discharge start time, and around the discharge end time are narrower than those in other time (periods). Since change in voltage values around the charge start time, around the charge end time, around the discharge start time, and around the discharge end time are larger than that in other time, data collection at fine intervals is required. Thus, the control unit 154 controls transmission data at intervals between measurement times as illustrated in FIG. 27.

In charging and discharging in which charging/discharging time is predetermined, in particular charging and discharging for supply and demand adjustment and the like, contract power and charging/discharging time are often set in advance. Thus, in such a case, by each power storage device concentrating the number of pieces of sampled data around a specific time, having the pieces of sampled data buffered in the memory unit 134, and performing data transmission during a preset time, it becomes possible to further improve deterioration estimation accuracy.

Note that, in the case in FIG. 27, measurement times around the charge start time may be, for example, measurement times around a time at which the voltage starts to rise. Measurement times around the charge end time may be, for example, measurement times around a time at which the voltage has risen to a peak. Measurement times around the discharge start time may be, for example, measurement times around a time at which the voltage starts to fall. Measurement times around the discharge end time may be, for example, measurement times around a time at which the voltage has fallen to a bottom.

The power storage device 104-1 has switches for performing cell balancing operation on an as-needed basis and cutting-off input/output power on an as-needed basis.

The information processing device 204, based on pieces of state data of each storage battery that are transmitted from one of the power storage devices 104-1 to 104-3, estimates a deterioration state of the storage battery. The information processing device 204 may be a server device, a general PC, or a mobile communication terminal and is required to be a device including functions of performing communication and predetermined processing. Constituent elements that the information processing device 204 includes and operation thereof may be the same as those in the first example embodiment.

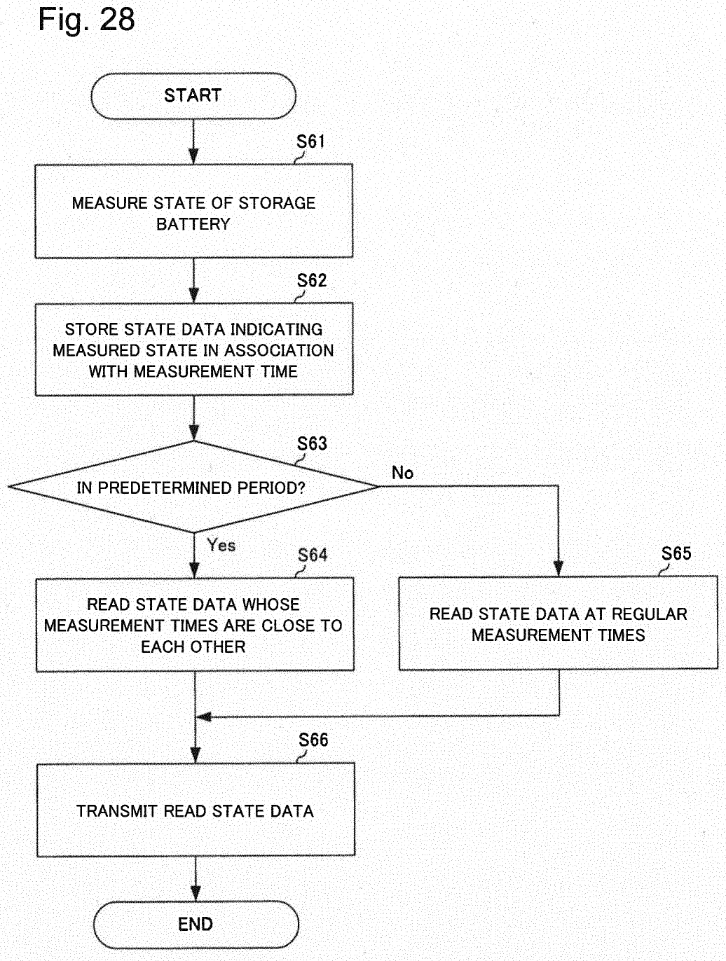

A reporting method in the power storage device 104-1 illustrated in FIG. 26 will be described below. FIG. 28 is a flowchart for a description of an example of the reporting method in the power storage device 104-1 illustrated in FIG. 26.

First, the measurement unit 124 measures a state of the storage battery 114 (step S61). Next, the memory unit 134 stores a piece of state data that indicates the state of the storage battery measured by the measurement unit 124 in association with a measurement time at which the state was measured (step S62).

Subsequently, the control unit 154 determines whether or not measurement times of pieces of state data to be transmitted by the transmission unit 144 are included in a predetermined period (step S63). The predetermined period is a predetermined period around a charge start time, a predetermined period around a charge end time, a predetermined period around a discharge start time, or a predetermined period around a discharge end time of the storage battery 114 as described above.

When the control unit 154 determines that the measurement times of the pieces of state data to be transmitted by the transmission unit 144 are included in a predetermined period, the control unit 154 instructs the transmission unit 144 to read pieces of state data the measurement times of which are close to each other (step S64). On the other hand, when the control unit 154 determines that the measurement times of the pieces of state data to be transmitted by the transmission unit 144 are not included in a predetermined period, the control unit 154 instructs the transmission unit 144 to read pieces of state data at regular measurement times (step S65).

Subsequently, the transmission unit 144 transmits the read pieces of state data from the memory unit 134 to the information processing device 204 (step S66).

In this way, among pieces of state data of a storage battery that each of the power storage devices 104-1 to 104-3 transmits to the information processing device 204, pieces of state data measured during a specific period are transmitted in such a way that measurement times of the pieces of state data have narrow intervals therebetween. During a period for which fluctuation in state data is large, such as a period of time when charging or discharging starts or ends, this configuration enables more precise data to be obtained than during other periods of time.

Note that, while, with regard to charging, it is preferable to use data at the time of charge start or end because the charging is performed with constant current, when a current value immediately before discharge end can be obtained, it is also possible to make a correction with the current value at the time of discharging. Thus, use of data relating to discharge start or end does not cause any problem. In particular, since values of current I in such a transient response become constant when charging and discharging are performed at a constant current, internal resistance R can be obtained without any correction. In addition, it becomes possible to comparatively easily obtain relaxation characteristics (voltage rises or falls in a curved line for a comparatively long period of time) that depend on a circuit constant of a parallel circuit of a resistor and a capacitor in an equivalent circuit model.

### Sixth Example Embodiment

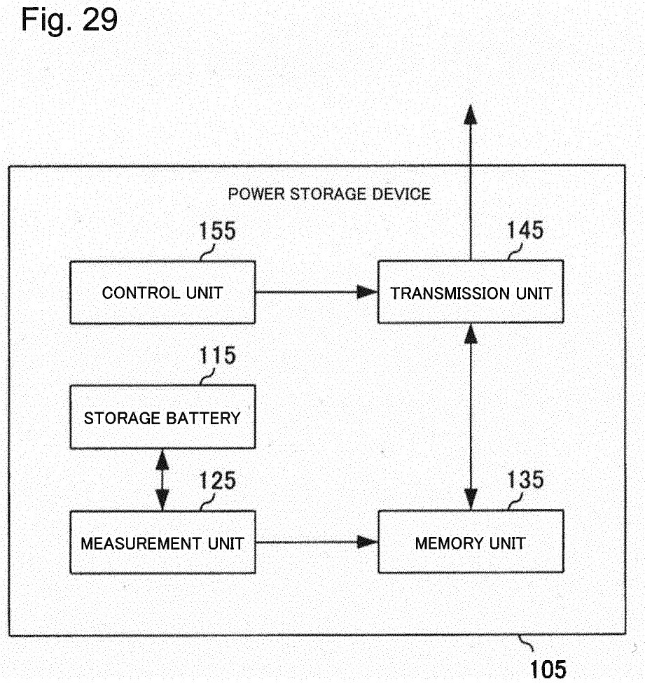

FIG. 29 is a diagram illustrating a sixth example embodiment using a power storage device of the present invention.

As illustrated in FIG. 29, the power storage device 105 of the present example embodiment includes a storage battery 115, a measurement unit 125 (measurement means), a memory unit 135 (memory means), a transmission unit 145 (transmission means), and a control unit 155 (control means). Note that, in FIG. 29, an example of principal constituent elements related to the present example embodiment among the constituent elements that the power storage device 105 of the present invention includes is illustrated.

The storage battery 115 is a secondary battery that can be charged and discharged. The storage battery 115 may be a plurality of battery cells that are connected in series, in parallel, or in series-parallel. The measurement unit 125 measures a state of the storage battery 115. The memory unit 135 is a database that stores pieces of state data that indicate the states of the storage battery 115 measured by the measurement unit 125 in association with measurement times at which the states were measured. The transmission unit 145 transmits a piece of state data stored in the memory unit 135 to a communication network. The control unit 155 controls the transmission unit 145 in such a way that each piece of state data transmitted by the transmission unit 145 is a piece of state data the measurement time of which differs each day.

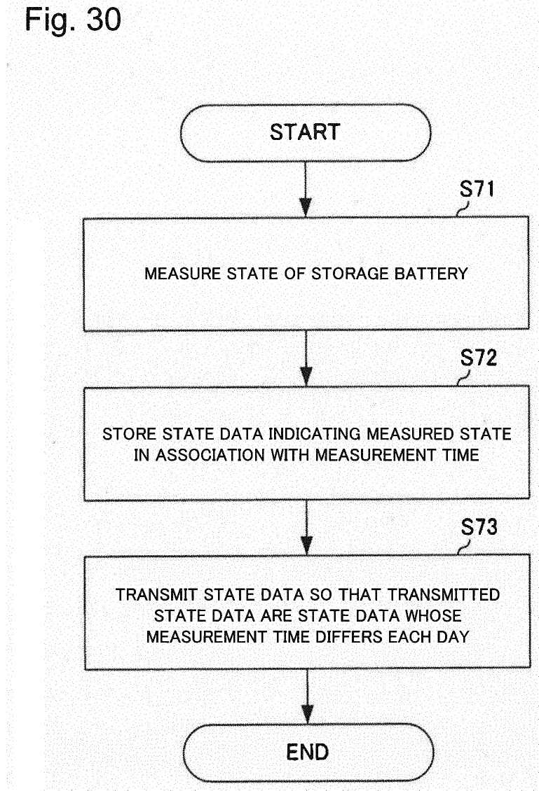

A reporting method in the power storage device 105 illustrated in FIG. 29 will be described below. FIG. 30 is a flowchart for a description of an example of the reporting method in the power storage device 105 illustrated in FIG. 29.

First, the measurement unit 125 measures a state of the storage battery 115 (step S71). Next, the memory unit 135 stores a piece of state data that indicates the states of the storage battery measured by the measurement unit 125 in association with a measurement time at which the state was measured (step S72).

Subsequently, the transmission unit 145, in accordance with control by the control unit 155, reads a piece of state data from the memory unit 135 in such a way that the piece of state data is a piece of state data the measurement time of which differs each day and transmits the read piece of state data to the communication network (step S73).

In this way, each piece of state data of the storage battery that the power storage devices 105 transmits to the communication network is configured to be a piece of state data the measurement time of which is shifted each day. This configuration enables precise data to be obtained even when the amount of data transmitted per day is set to be small basis in order to reduce a load on an information processing device.

### Seventh Example Embodiment

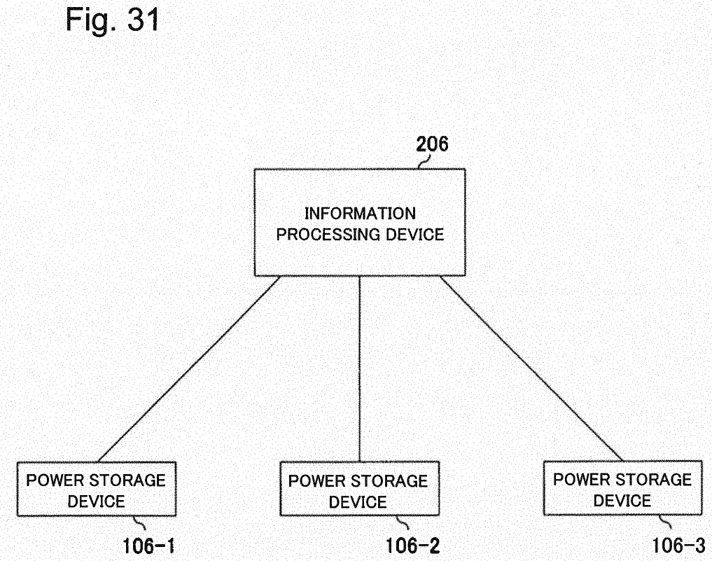

FIG. 31 is a diagram illustrating a seventh example embodiment (a power storage system) using power storage devices of the present invention. As illustrated in FIG. 31, the present example embodiment includes a plurality of power storage devices 106-1 to 106-3 and an information processing device 206.

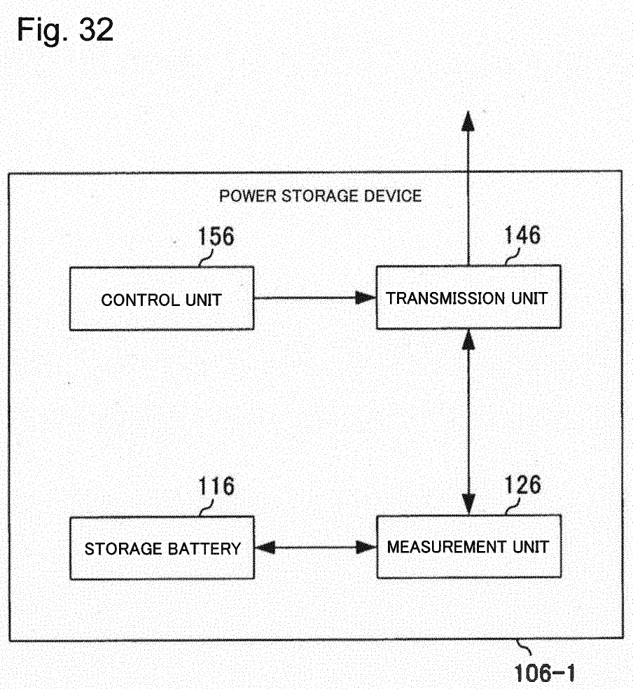

FIG. 32 is a diagram illustrating an example of an internal configuration of the power storage device 106-1 illustrated in FIG. 31. As illustrated in FIG. 32, the power storage device 106-1 illustrated in FIG. 31 includes a storage battery 116, a measurement unit 126, a transmission unit 146, and a control unit 156. Note that, in FIG. 32, an example of principal constituent elements related to the present example embodiment among the constituent elements that the power storage device 106-1 illustrated in FIG. 31 includes is illustrated. In addition, internal configurations of the power storage devices 106-2 and 106-3 illustrated in FIG. 31 may be the same as the internal configuration of the power storage device 106-1.

The storage battery 116 is a secondary battery that can be charged and discharged. The measurement unit 126 measures a state of the storage battery 116. The transmission unit 146 transmits a piece of state data that indicate the state measured by the measurement unit to the information processing device 206. The control unit 156 controls a transmission timing in such a way that the transmission unit 146 transmits a piece of state data at a timing that is mutually different from timings at which the power storage devices 106-2 and 106-3, which are power storage devices other than the power storage device 106-1 among the power storage devices 106-1 to 101-3, respectively transmit pieces of state data.

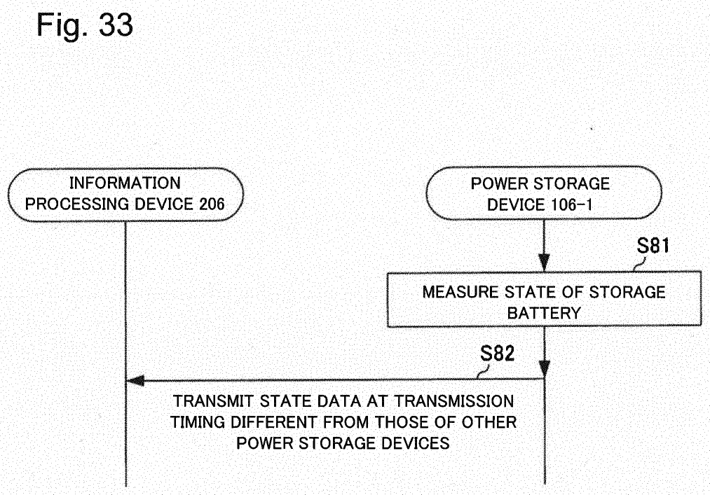

A reporting method in the power storage system illustrated in FIG. 31 will be described below. FIG. 33 is a sequence diagram for a description of an example of the estimation method in the power storage system illustrated in FIG. 31.

First, the measurement unit 126 of the power storage device 106-1 measures a state of the storage battery 116 of the power storage device 106-1 (step S81). Next, the transmission unit 146, in accordance with control by the control unit 156, transmits a piece of state data at a timing that is mutually different from timings at which the power storage devices 106-2 and 106-3, which are power storage devices other than the power storage device 106-1, respectively transmit pieces of state data (step S82).

In this way, the power storage devices 106-1 to 106-3 transmit pieces of state data indicating states of the storage batteries to the information processing device 206 at timings different from one another. This configuration enables congestion in the communication network to be prevented from occurring.

### Eighth Example Embodiment

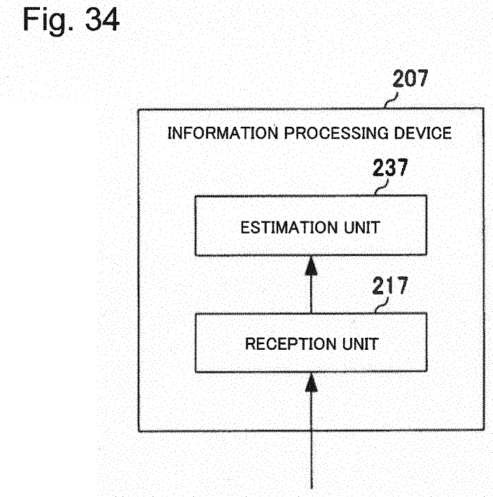

FIG. 34 is a diagram illustrating an example embodiment of an information processing device of the present invention.

As illustrated in FIG. 34, the information processing device 207 of the present example embodiment includes a reception unit 217 and an estimation unit 237. Note that, in FIG. 34, an example of principal constituent elements related to the present example embodiment among the constituent elements that the power storage device 207 of the present invention includes is illustrated.

The reception unit 217 receives a plurality of pieces of state data that are transmitted from a power storage device and that indicate states of a storage battery that the power storage device includes. The estimation unit 237 estimates a deterioration state of the storage battery, based on the states that the plurality of pieces of state data received by the reception unit 217 indicate.

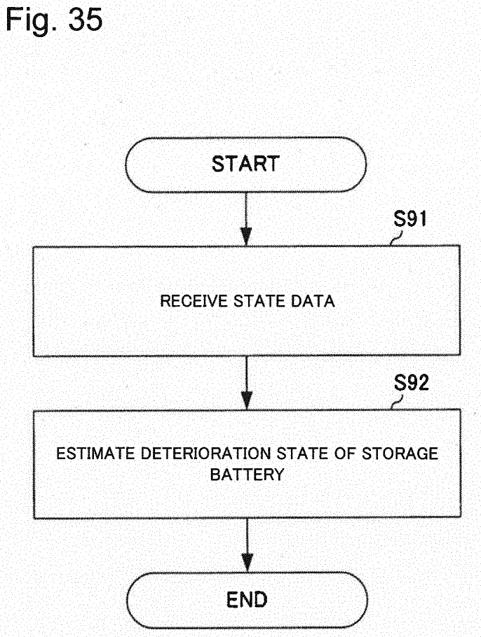

An estimation method in the information processing device 207 illustrated in FIG. 34 will be described below. FIG. 35 is a flowchart for a description of the estimation method in the information processing device 207 illustrated in FIG. 34.

When pieces of state data of a storage battery are transmitted from a power storage device, the reception unit 217 receives the pieces of state data (step S91). Subsequently, the estimation unit 237 estimates a deterioration state of the storage battery, based on states that the plurality of pieces of state data received by the reception unit 217 indicate (step S92).

In this way, it is possible to estimate a deterioration state of a storage battery, based on pieces of state data that are transmitted from a power storage device.

Although the present invention was described above through eight example embodiments, the present invention may be embodied as an example embodiment constituted by combining all or some of the eight example embodiments.

Respective constituent elements disposed in each of the devices described above indicate not elements in units of hardware components but elements in units of functions. In addition, processing performed by the respective constituent elements may be performed by logical circuits that are respectively produced in accordance with purposes of the processing. Further, the respective constituent elements may be achieved by recording a computer program (hereinafter, referred to as a program) in which processing instructions are described as a process into a recording medium that is readable by each of the respective devices and making each of the respective devices read and execute the program recorded in the recording medium. The recording medium that is readable by each of the respective devices refers to not only a portable recording medium, such as a floppy (registered trademark) disc, a magneto optical disc, a digital versatile disc (DVD), a compact disc (CD), and a Blu-ray (registered trademark) disc, but also a memory, such as a read only memory (ROM) and a random access memory (RAM), and a hard disc drive (HDD) that are built-in in each of the respective devices. The program recorded in the recording medium is read by a central processing unit (CPU) disposed in each of the respective devices, and the same processing as the processing described above is performed under the control by the CPU. In the performance of the processing, the CPU is a device that operates as a computer that executes the program read from the recording medium recording the program.

Note that the present invention is not limited to the example embodiments described above.

All or a portion of the respective example embodiments described above may be described as in the following supplementary notes, but the present invention is not limited thereto.

(Supplementary Note 1)

A power storage device including:

a measurement unit that measures a state of a storage battery;

a memory unit that stores a piece of state data that indicates a state measured by the measurement unit in association with a measurement time at which the state is measured;

a transmission unit that transmits a piece of state data stored in the memory unit to a communication network; and

a control unit that controls the transmission unit in such a way that each piece of state data transmitted by the transmission unit is a piece of state data the measurement time of which differs each day.

(Supplementary Note 2)

The power storage device according to supplementary note 1, wherein

the control unit, depending on time, changes an interval between adjacent measurement times of pieces of state data transmitted by the transmission unit.

(Supplementary Note 3)

The power storage device according to supplementary note 2, wherein

the control unit makes the interval between adjacent measurement times during a predetermined period around a charge start time, a predetermined period around a charge end time, a predetermined period around a discharge start time, and a predetermined period around a discharge end time of the storage battery narrower than the interval between adjacent measurement time during the other periods.

(Supplementary Note 4)

The power storage device according to any one of supplementary notes 1 to 3, wherein

the transmission unit transmits a plurality of pieces of state data at a time.

(Supplementary Note 5)

The power storage device according to any one of supplementary notes 1 to 4, wherein

the state data include at least one of voltage, current, a state of charge (SOC), temperature, a current integrated value, and a total charged/discharged power amount of the storage battery.

(Supplementary Note 6)

An information processing device including:

a reception unit that receives a plurality of pieces of state data that are transmitted from a power storage device and that indicate states of a storage battery that the power storage device includes; and

an estimation unit that estimates a deterioration state of the storage battery, based on the states that the plurality of pieces of state data received by the reception unit indicate.

(Supplementary Note 7)

The information processing device according to supplementary note 6, wherein

the estimation units superimposes pieces of state data that are received by the reception unit and each of which corresponds to a measurement time that differs each day on one another in accordance with the measurement times and estimates a deterioration state of the storage battery, based on a result of the superimposition.

(Supplementary Note 8)

The information processing device according to supplementary note 6 including

a grouping unit that groups a plurality of power storage devices into a group(s), wherein

the estimation unit, with respect to each group grouped by the grouping means, estimates a deterioration state of the storage battery(ies), using pieces of state data received by the reception unit.

(Supplementary Note 9)

The information processing device according to supplementary note 8, wherein

the estimation unit, with respect to each group grouped by the grouping unit, superimposes pieces of state data that are received by the reception unit on one another in accordance with measurement times and estimates a deterioration state of the storage battery(ies), based on a result of the superimposition.

(Supplementary Note 10)

The information processing device according to supplementary note 8 or 9, wherein

the grouping unit groups the plurality of power storage devices, based on areas where the power storage devices are placed.

(Supplementary Note 11)

The information processing device according to supplementary note 8 or 9, wherein

the grouping unit groups the plurality of power storage devices, based on placement times when the power storage devices were placed.

(Supplementary Note 12)

The information processing device according to supplementary note 8 or 9, wherein

the grouping unit groups the plurality of power storage devices, based on whether or not each of the power storage devices includes a plurality of the storage batteries.

(Supplementary Note 13)

The information processing device according to supplementary note 8 or 9, wherein

the grouping unit, with respect to the power storage devices cooperating with photovoltaics, groups the plurality of power storage devices, based on sunshine duration during which the photovoltaics are exposed to sunlight.

(Supplementary Note 14)

The information processing device according to supplementary note 8 or 9, wherein

the grouping unit groups the plurality of power storage devices, based on whether or not manufacturers of the power storage devices are the same.

(Supplementary Note 15)

A reporting method including the steps of:

measuring a state of a storage battery;

storing a piece of state data that indicates the measured state in association with a measurement time at which the state is measured in a database; and

transmitting, among pieces of state data stored in the database, a piece of state data the measurement time of which differs each day to a communication network.

(Supplementary Note 16)

An estimation method including the steps of:

receiving a plurality of pieces of state data that are transmitted from a power storage device and that indicate states of a storage battery that the power storage device includes; and

estimating a deterioration state of the storage battery, based on states that the received plurality of pieces of state data indicate.

(Supplementary Note 17)

The estimation method according to supplementary note 16 including the steps of:

superimposing the received pieces of state data each of which corresponds to a measurement time that differs each day on one another in accordance with the measurement times; and

estimating a deterioration state of the storage battery, based on a result of the superimposition.

(Supplementary Note 18)

The estimation method according to supplementary note 16 including the steps of:

grouping a plurality of power storage devices into a group(s); and

with respect to each of the grouped group(s), estimating a deterioration state of the storage battery(ies), using the received pieces of state data.

(Supplementary Note 19)

A program for causing a computer to perform the steps of:

measuring a state of a storage battery;

storing a piece of state data that indicates the measured state in association with a measurement time at which the state is measured in a database; and

transmitting, among pieces of state data stored in the database, a piece of state data the measurement time of which differs each day to a communication network.

(Supplementary Note 20)

A program for causing a computer to perform the steps of:

receiving a plurality of pieces of state data that are transmitted from a power storage device and that indicate states of a storage battery that the power storage device includes; and

estimating a deterioration state of the storage battery, based on states that the received plurality of pieces of state data indicate.

(Supplementary Note 21)

The program according to supplementary note 20 causing the computer to perform the steps of:

superimposing the received pieces of state data each of which corresponds to a measurement time that differs each day on one another in accordance with the measurement times; and

estimating a deterioration state of the storage battery, based on a result of the superimposition.

(Supplementary Note 22)

The program according to supplementary note 20 causing the computer to perform the steps of:

grouping a plurality of power storage devices into a group(s); and

with respect to each of the grouped group(s), estimating a deterioration state of the storage battery(ies), using the received pieces of state data.

(Supplementary Note 23)

A power storage system including an information processing device and a plurality of power storage devices, wherein

each of the plurality of power storage devices includes:
a measurement unit that measures a state of a storage battery that the power storage device includes;
a transmission unit that transmits a piece of state data that indicates a state measured by the measurement unit to the information processing device; and
a control unit that controls a transmission timing at which the transmission unit transmits the piece of state data, wherein
the control unit controls the transmission timing in such a way that the transmission unit transmits the piece of state data at a timing that is mutually different from timings at which a power storage device(s) other than the power storage device among the plurality of power storage devices transmit(s) a piece(s) of state data.

(Supplementary Note 24)

The power storage system according to supplementary note 23, wherein

the control unit rotates the transmission timing among the plurality of power storage devices each day.

(Supplementary Note 25)

The power storage system according to supplementary note 23 or 24, wherein

the information processing device notifies each of the plurality of power storage devices of a transmission timing that is mutually different from transmission timings at which a power storage device(s) other than the power storage device transmit(s) a piece(s) of state data, and the control unit controls the transmission timing in such a way that the transmission unit transmits the piece of state data at a timing that is notified by the information processing device.

(Supplementary Note 26)

The power storage system according to any one of supplementary notes 23 to 25, wherein

the control unit, depending on time, changes an interval between adjacent measurement times of pieces of state data transmitted by the transmission unit.

(Supplementary Note 27)

The power storage system according to supplementary note 26, wherein

the control unit makes the interval between adjacent measurement times during a predetermined period around a charge start time, a predetermined period around a charge end time, a predetermined period around a discharge start time, and a predetermined period around a discharge end time of the storage battery narrower than the interval between adjacent measurement times during the other periods.

(Supplementary Note 28)

The power storage system according to any one of supplementary notes 23 to 27, wherein

the information processing device estimates a deterioration state of the storage battery, based on pieces of state data that are transmitted from each of the plurality of power storage devices.

(Supplementary Note 29)

The power storage system according to any one of supplementary notes 23 to 28, wherein

the state data includes at least one of voltage, current, a state of charge (SOC), temperature, a current integrated value, and a total charged/discharged power amount of the storage battery.

As above, the present invention has been described based on the exemplary embodiments. An exemplary embodiment is just an illustration, and various kinds of changes, addition or subtraction and combinations may be added to each of the above-mentioned exemplary embodiments unless it deviates from the main points of the present invention. It is understood by a person skilled in the art that modification made by adding such changes, addition/subtraction and combinations are also included in the scope of the present invention.

This application claims priority based on Japanese Patent Application No. 2016-169444, filed on Aug. 31, 2016, the entire disclosure of which is incorporated herein by reference.

### REFERENCE SIGNS LIST

100-1 to 100-3, 101-1 to 101-3, 102-1 to 102-3, 103-1 to 103-3, 104-1 to 104-3, 105, 106-1 to 106-3 Power storage device
110, 111, 113, 114, 115, 116 Storage battery
120, 121, 123, 124, 125, 126 Measurement unit
130, 131, 133, 134, 135 Memory unit
140, 141, 143, 144, 145, 146 Transmission unit
150, 151, 153, 154, 155, 156 Control unit
200, 201, 202, 203, 204, 206, 207 Information processing device
210, 211, 212, 217 Reception unit
222 Grouping unit
230, 231, 232, 237 Estimation unit
241 Transmission timing control unit
300, 301, 302, 303, 304 Communication network

1. A power storage device comprising:
measurement unit measuring a state of a storage battery;
memory unit storing a piece of state data that indicates a state measured by the measurement unit in association with a measurement time at which the state is measured;
transmission unit transmitting a piece of the state data stored in the memory means to a communication network; and
control unit controlling the transmission unit in such a way that each piece of the state data transmitted by the transmission unit is a piece of the state data the measurement time of which differs each day.

2. The power storage device according to claim 1, wherein
the control unit, depending on time, changes an interval between adjacent measurement times of pieces of the state data transmitted by the transmission unit.

3. The power storage device according to claim 2, wherein
the control unit makes the interval between adjacent measurement times during a predetermined period around a charge start time, a predetermined period around a charge end time, a predetermined period around a discharge start time, and a predetermined period around a discharge end time of the storage battery narrower than the interval between adjacent measurement times during the other periods.

4. The power storage device according to claim 1, wherein
the transmission unit transmits a plurality of pieces of the state data at a time.

5. The power storage device according to claim 1, wherein
the state data includes at least one of voltage, current, a state of charge (SOC), temperature, a current integrated value, and a total charged/discharged power amount of the storage battery.

6. An information processing device comprising:
reception unit receiving a plurality of pieces of state data that are transmitted from a power storage device and that indicate states of a storage battery that the power storage device includes; and
estimation unit estimating a deterioration state of the storage battery, based on the states that the plurality of pieces of the state data received by the reception unit indicate.

7. The information processing device according to claim 6, wherein
the estimation unit superimposes pieces of the state data that are received by the reception unit and each of which corresponds to a measurement time that differs each day on one another in accordance with the measurement times and estimates a deterioration state of the storage battery, based on a result of the superimposition.

8. The information processing device according to claim 6 further comprising
grouping unit grouping a plurality of the power storage devices into a group(s), wherein
the estimation unit, with respect to each group grouped by the grouping unit, estimates a deterioration state of the storage battery(ies), using pieces of the state data received by the reception unit.

9. The information processing device according to claim 8, wherein
the estimation unit, with respect to each group grouped by the grouping unit, superimposes pieces of the state data that are received by the reception unit on one another in accordance with measurement times and estimates a deterioration state of the storage battery(ies), based on result of the superimposition.

10. The information processing device according to claim 8, wherein
the grouping unit groups a plurality of the power storage devices, based on areas where the power storage devices are placed.

11. The information processing device according to claim 8, wherein
the grouping unit groups a plurality of the power storage devices, based on placement times when the power storage devices were placed.

12. The information processing device according to claim 8, wherein
the grouping unit groups a plurality of the power storage devices, based on whether or not each of the power storage devices includes a plurality of the storage batteries.

13. The information processing device according to claim 8, wherein
the grouping unit, with respect to the power storage devices cooperating with photovoltaics, groups a plurality of the power storage devices, based on sunshine duration during which the photovoltaics are exposed to sunlight.

14. The information processing device according to claim 8, wherein
the grouping unit groups a plurality of the power storage devices, based on whether or not manufacturers of the power storage devices are the same.

15. (canceled)

16. An estimation method comprising:
receiving a plurality of pieces of state data that are transmitted from a power storage device and that indicate states of a storage battery that the power storage device includes; and
estimating a deterioration state of the storage battery, based on the states that the received plurality of pieces of the state data indicate.

17. The estimation method according to claim 16 comprising:
superimposing received pieces of the state data each of which corresponds to a measurement time that differs each day on one another in accordance with the measurement times; and
estimating a deterioration state of the storage battery, based on a result of the superimposition.

18. The estimation method according to claim 16 comprising:
grouping a plurality of the power storage devices into a group(s); and
with respect to each of the grouped group(s), estimating a deterioration state of the storage battery(ies), using received pieces of the state data.

19. (canceled)

20. A recording medium recording a program for causing a computer to perform:
receiving a plurality of pieces of state data that are transmitted from a power storage device and that indicate states of a storage battery that the power storage device includes; and
estimating a deterioration state of the storage battery, based on states that the received plurality of pieces of the state data indicate.

21. The recording medium according to claim 20, the program causing the computer to perform:
superimposing received pieces of the state data each of which corresponds to a measurement time that differs each day on one another in accordance with the measurement times; and
estimating a deterioration state of the storage battery, based on a result of the superimposition.

22. The recording medium according to claim 20, the program causing the computer to perform:
grouping a plurality of the power storage devices into a group(s); and
with respect to each of the grouped group(s), estimating a deterioration state of the storage battery(ies), using received pieces of the state data.

23. (canceled)

24. (canceled)

25. (canceled)

26. (canceled)

27. (canceled)

28. (canceled)

29. (canceled)
